(19) United States
(12) Patent Application Publication
(10) Pub. No.: US 2005/0217722 A1
(43) Pub. Date: Oct. 6, 2005

(54) Organic photoelectric conversion element and method of producing the same, organic photodiode and image sensor using the same, organic diode and method of producing the same

(76) Inventors: Takahiro Komatsu, Kasuga-shi (JP); Kei Sakanoue, Fukuoka-shi (JP); Ryuichi Yatsunami, Fukuoka-shi (JP); Masakazu Mizusaki, Fukuoka-shi (JP); Takashi Kitada, Ogori-shi (JP); Masahiro Inoue, Onojyo-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/092,716

(22) Filed: Mar. 30, 2005

(30) Foreign Application Priority Data
Mar. 31, 2004 (JP) P. 2004-102861
Mar. 15, 2005 (JP) P. 2005-072555
Mar. 15, 2005 (JP) P. 2005-072556

(51) Int. Cl. H01L 31/00

(52) U.S. Cl. 136/263

(57) ABSTRACT

The organic photoelectric conversion element in accordance with the invention comprises at least one pair of electrodes 12 and 16, a photoelectric conversion region (layer) 15 arranged between the electrodes and containing at least an electron donating organic material and an electron accepting organic material, and a buffer layer 14 containing at least one inorganic matter and inserted between the photoelectric conversion region and at least one electrode of the above-cited pair of electrodes.

### BACKGROUND OF THE INVENTION

1. Field of the Invention

The present invention relates to an organic photoelectric conversion element, a method of producing the same, and, in particular, an organic photoelectric conversion element having stable characteristics in expectation of the application to solar cells and photo-sensors. Further, the present invention relates to an organic photodiode capable of converting light to electricity by making use of the pn junction of organic semiconductor materials, and an image sensor using the same and capable of reading the information of documents as well as substances. Furthermore, the present invention relates to an organic diode and a method of producing the same, and in particular such an organic diode that has high rectification property in expectation of the application to electronic parts.

2. Related Art

An inorganic solar cell using silicon such as amorphous silicon is a clean device which is under study for practical application. However, recently there arises a serious problem with such an inorganic solar cell acting as a clean electric power generator with respect to the environmental load for waste disposal. Under such circumstances, photoelectric conversion elements using organic semiconductor materials are under development for practical application due to light environmental load for waste disposal as well as low production cost. For example, such conventional art is disclosed in Japanese Patent publication No. 8-500701/(1996).

Such an organic photoelectric conversion element is designed so as to generate electromotive force between electrodes due to the associated photoelectric phenomenon when light impinges on the organic semiconductor material, and is configured, as roughly shown in FIG. 5, by stacking a substrate 1, a positive electrode 2, a charge transport layer 3, a photoelectric conversion layer 4 and a negative electrode 5 (5a and 5b).

The photoelectric conversion layer 4 have an electron donating material and an electron accepting material.

When light is incident on the photoelectric conversion layer 4, light absorption occurs there to give rise to excitons consisting of electron-hole pairs. Thereafter, carriers are separated whereby electrons move to the negative electrode 5 through an electron accepting semiconductor material and holes move to the positive electrode 2 through an electron donating semiconductor material. Via such processes, an electromotive force generates between the two electrodes, and it becomes possible to take out an electric power by connecting these electrodes to an external circuit.

The photoelectric phenomenon described above tends to occur at the interface of two materials having different electron affinities or ionization potentials. And, to produce a highly efficient photoelectric conversion element, it is necessary to bring plural materials of different electron affinities as set forth above into contact at a broad interface area. Further, from the viewpoint of effective use of the generated carriers, it is desirable that the carriers are efficiently transported to the positive or negative electrode 2 or 5 without the recombination of the excitons. Moreover, it is significant to minimize the number of the defects in the photoelectric conversion layer 4 so that the carriers are not trapped by the defects and a leak current is prevented from generation.

To meet those various requirements, research and development of organic photoelectric conversion elements are being devotedly carried out from both of materialistic and process viewpoints, now having achieved an energy conversion efficiency of about 10% for dye sensitization-type ones and 3% for solid thin film type ones as the result of the enhancement of carrier separation efficiency.

However, the above-described organic photoelectric conversion element has had a problem of being liable to undergo performance deterioration, leading to a short product life. Namely, there has been a problem that, in cases where the organic photoelectric conversion element is used as a product such as a solar cell or photo sensor, the currently available organic photoelectric conversion element cannot sufficiently satisfy life requirement for any type of application, though the life required for each of these products is different.

Additionally, an image sensor which converts the information of document as well as substances into electric information by using light is used in a wide spectrum of products such as facsimile machines, scanners and digital cameras. Such an information-reading sensor is comprised of plural photo-receptive parts for the conversion of light signals to electric ones, and constitutes an information-reading module represented by CIS by combining other parts such as a light source unit, a lens system such as a selfoc lens. Conventionally, for such photo-receptive part, inorganic photodiodes, photoconductors and phototransistors, and applied products thereof have mainly been adopted. Such an inorganic material-based photo-receptive part involves the problem of the difficulty in cost reduction because the manufacture of the photo-receptive part requires large-scale semiconductor processes and a large number of steps, and moreover because area expansion is difficult. Accordingly, as set forth in G. Yu, Y Cao, J. Wang, J. McElvain and A. J. Heeger, Synth. Met. 102, 904 (1999), cost reduction is under trial by adopting an organic photodiode comprising organic materials for the photo-receptive part.

Here, an organic photodiode is described with reference to the drawings.

FIG. 10 is a cross-sectional view of the essential part of an ordinary organic photodiode. In FIG. 10, 120 designates a substrate, 121 a positive electrode, 122 a photoelectric conversion region, 123 an electron donating layer comprising an electron donating material, 124 an electron accepting layer comprising an electron accepting material, and 125 a negative electrode, respectively. This organic photodiode is provided with a positive electrode comprising a transparent electro-conductive film of ITO or the like formed by sputtering or resistive heating vapor deposition on a light-transmitting conductive substrate such as glass, a photoelectric conversion region comprising an electron donating layer and an electron accepting layer both formed by resistive heating vapor deposition on the positive electrode, and a negative electrode made of a metal formed on the region similarly by resistive heating vapor deposition. When light is irradiated on the organic photodiode having the foregoing configuration, light absorption takes place at the photoelectric conversion region to form excitons. In succession, carriers are separated and electrons move through the electron accepting layer to the negative electrode while holes move through the electron donating layer to the positive electrode. Due to such movements, an electromotive force generates between the two electrodes, whereby electric signal can be taken out by connecting an external circuit.

In recent years, with the aim of further cost reduction, bulk hetero-junction-type (referred to as BH-type hereinafter) organic photodiodes using a photoelectric conversion region 126 consisting of the mixture of an electron donating material and an electron accepting material as shown in FIG. 11 are being studied. In FIG. 11, the substrate 120, the positive electrode 121 and the negative electrode 125 except the photoelectric conversion region are the same as in the aforementioned ordinary organic photodiode, but in this BH-type organic photodiode, a pn junction, which has been conventionally formed with the two layers of electron donating and accepting ones, is formed with only a single layer comprising the mixture of an electron donating material and an electron accepting material. Thus, this type of photodiode is attracting considerable attention because of the simplicity of the process with which the pn junction is formed, i.e., only by spin-coating the solution of the mixture.

As has been described heretofore, the organic photodiode is an seriously attention-attracting element since it can exhibit the same function as that of the inorganic photodiode in spite of the fact that it can be manufactured with an extremely simple method.

Next, the configuration of an image sensor using such an organic photodiode for the photo-receptive part is shown in FIG. 12, wherein 127 designates an organic photodiode acting as a photo-receptive part, 128 an optical system including a lens, and 129 a light source unit. In such an image sensor, the light reflected by an object represented by a document 130 or the direct light is guided to the photo-receptive part via the optical system, and converted to electric signal corresponding to the light amount. Meanwhile, usually plural photo-receptive parts are arranged linearly or in planar manner so as to lie side by side. But, in the case where carrier leakage between the contiguous photo-receptive parts are negligible due to the low carrier mobility of the organic material, the organic material may be formed in the entire area without any patterning whereby individual photoreceptive parts are not separated from each other.

As stated hereinabove, it is possible to produce an image sensor by using an inorganic photodiode for the photo-receptive part. However, the conventional organic photodiode was not suited for the applications requiring high-speed, high-sensitivity image sensors since the organic photodiode had a very large dark current. In the following, the reason for this drawback is briefly explained.

In an ordinary image sensor, the charge generated in the photodiode is not directly read because of the low photoelectric conversion efficiency of the photodiode; instead, after the accumulation of charge to a pre-determined value under the application of a reverse bias to the photodiode in advance, the accumulated charge is cancelled by the charge generated by light irradiation to read information. According to such a reading method described above and called charge accumulation mode, the accumulated charge can be cancelled by the irradiated light, except the period for charge accumulation in the photodiode and the period for reading the reduced charge a large output voltage can be attained, even if the photo-current per unit time is extremely small. But, what is important in this charge accumulation mode, the leak current while light is not irradiated, i.e., the dark current, must be small. As stated above, in the charge accumulation mode, a reverse bias is applied to the photodiode in advance, whereby, if the dark current of the photodiode is large, the accumulated charge is gradually lost, leading to noticeable drop of the S/N ratio representing the charge difference for light irradiation from no light irradiation. In some cases, detection of the charge amount reduced by light irradiation becomes quite difficult. Since the conventional organic photodiode suffered from a large dark current, there were problems that the resulting S/N ratio is small and that only low-sensitivity image sensor can be produced. In particular, in the BH-type element, the influence of the dark current discussed above is serious, and the solution of the problem has been a pressing need.

Further, in recent years, research and development of organic electronic devices using organic semiconductor materials for the functional part of the devices are extensively being carried out. Among such devices, organic electroluminescence elements are attracting the highest attention, and applications to various light sources and displays are in rapid advance. In addition, trials to fabricate the circuit unit for driving a device such as an organic electroluminescence element with organic matters are also under investigation. One significant feature of organic electronic devices is the ability of exerting various characteristics by appropriate material selection, and moreover organic electronic devices have advantages of low environmental load for disposal and low production cost due to the unnecessity of large-scale production apparatuses such as are required for the production of conventional inorganic semiconductors. The study of such organic electronic devices is considered to prevail more and more in a near future, and organic electronic devices are presumed to replace part of devices that have been accomplished only with inorganic materials.

Now, various electronic parts required for electric circuits such as a diode, condenser, resistor and transistor can be constituted with organic semiconductor materials, but their characteristics are not at the level of full satisfaction as yet. An organic diode acts to achieve rectifying capability by forming a pn junction with organic semiconductor materials, and has a basic configuration as shown in FIG. 13, comprising a substrate 213, a positive electrode 214, an organic p-type semiconductor layer 215, an organic n-type semiconductor layer 216 and a negative electrode 217, all stacked together. A pn junction is formed between these organic p-type and n-type semiconductor layers to provide rectifying capability (For example, refer to non-patent literature P. Peumans and S. R. Forrest: Applied Physics Letters, 79, pp. 126-128 (2001)).

Recently, for the purpose of still further cost reduction, the study of bulk hetero-junction type (referred to as BH-type hereinafter) organic diode using a mixture layer 18 comprising an organic p-type semiconductor material and an organic n-type semiconductor material as shown in FIG. 7 is being conducted (For example, refer to non-patent literature G Yu, J. Gao, J. C. Hummelen, F. Wudl and J. Heeger: Science, 270, pp. 1789-1791 (1995)). In this BH-type organic diode, the pn junction, which has been conventionally formed with two layers of a p-type one and an n-type one, is formed only with a single layer of the mixture containing a p-type material and an n-type material, and has the feature that a pn junction can be readily formed, for example, by spin-coating a solution of the mixture. Such a production method is attracting attention due to its process simplicity.

To produce a high performance diode, i.e., a diode exhibiting a high rectification ratio, it is important to make the normal bias current large and sufficiently decrease the reverse bias current. Usually, the organic layer of an organic diode is formed by vacuum vapor deposition or spin coating, and has an extremely small thickness in the order of several hundred nanometers. Therefore, if there exists a thin part or defect in the layer, the leak current becomes large under reverse bias application, resulting in a small rectification ratio. This problem particularly seriously influences the performance of the BH-type organic diode, and the solution thereof is urgently demanded.

### SUMMARY OF THE INVENTION

An object of the present invention is to provide a long life organic photoelectric conversion element together with the intention of performance stabilization. Another object of the invention is to reduce the dark current of organic photodiodes and to provide an image sensor having a high sensitivity. Moreover, the invention provides an organic diode which reduces the reverse bias current and has a high rectification ratio, and the production method of the same.

According to first aspect of the invention, the organic photoelectric conversion element comprises at least a pair of electrodes, a photoelectric conversion region arranged between the electrodes and containing at least an electron donating organic material and an electron accepting material, and a buffer layer made of at least one inorganic matter and arranged between the photoelectric conversion region and at least one of the pair of the electrodes.

A long life organic photoelectric conversion element can be obtained by virtue of this configuration with which the performance is stabilized by suppressing the diffusion of the element-constituting materials.

Further, in the organic photoelectric conversion element of the invention the photoelectric conversion region contains an organic thin film.

And, in the organic photoelectric conversion element of the invention, the organic thin film contains a polymer film formed by coating on one of the electrodes.

Since, in such a constitution, the photoelectric conversion region is formed by coating, the element can be produced without via a vacuum process. In addition, the buffer layer may be formed by coating, too.

Further, the organic photoelectric conversion element of the invention includes such one in which the electron donating material is comprised of an electro-conductive polymer material.

Still further, in the organic photoelectric conversion element of the invention, the electron accepting material contains at least one of a modified or unmodified fullerene compound and a carbon nano-tube compound.

With such a constitution, since electron mobility is enhanced by the modified or unmodified fullerene compound or carbon nano-tube compound, the electron supplied by the electron donating organic material can be transported to the negative electrode at a high velocity by virtue of the high electron mobility of the electron accepting material, leading to the enhancement of photoelectric conversion efficiency. At the same time, cost down can be attained since the electron donating organic material and the electron accepting material can be used in a mixed state.

According to second aspect of the invention, the organic photodiode of the invention comprises at least a pair of electrodes, and a photoelectric conversion region provided between the electrodes and containing at least an electron donating material and at least an electron accepting material mixed together, and a carbon layer arranged between the photoelectric conversion region and at least one of the pair of electrodes, and is characterized by the capability of charge accumulation. This carbon layer can reduce the carrier injection from the electrode to the organic layer, thus markedly reducing the dark current.

In addition, the image sensor of the invention can achieve high sensitivity and high performance information read-out by virtue of adopting an organic photodiode exhibiting a low dark current and capable of charge accumulation for the photo-receptive part.

According to the invention, not only the dark current of an organic photodiode is markedly reduced, but also easy and inexpensive production of a highly sensitive, high performance image sensor becomes possible by using the organic photodiode as the photo-receptive part of the image sensor.

According to third aspect of the invention, the organic diode of the invention comprises at least a pair of electrodes, and a hetero-junction layer provided between the electrodes and containing at least an electron donating material and at least an electron accepting material mixed together, and a carbon layer arranged between the hetero-junction layer and at least one of the pair of electrodes. And this carbon layer largely reduces the carrier injection from the electrode to the organic layer, thus markedly reducing the leak current under reverse bias application.

Further, the organic diode of the invention uses a layer in which an electron donating material and an electron accepting material are dispersed as a hetero-junction layer. With such a configuration, it is possible to readily produce an organic diode by a simple production method.

Still further, the carbon layer for the reduction of reverse bias current is formed by sputtering, whereby, since a homogeneous film exhibiting good step coverage can be formed, the hetero-junction layer is readily formed, enabling consistent diode production.

According to the invention, not only an organic diode using an organic hetero-junction can be produced easily and inexpensively, but also a high rectification ratio can be imparted to the diode.

### BRIEF DESCRIPTION OF THE DRAWINGS

FIG. 1 is a diagram showing the organic photoelectric conversion element in Embodiment 1 of the invention;

FIG. 2 is a diagram to explain Example 1 of the invention;

FIG. 3 is a diagram to explain Example 1 of the invention;

FIG. 4 is a diagram showing the organic photoelectric conversion element in Embodiment 2 of the invention;

FIG. 5 is a diagram showing a conventional organic photoelectric conversion element;

FIG. 6 shows the cross-sectional view of the essential part of the organic photodiode in one embodiment of the invention;

FIG. 7 shows a bird-eye view of the image sensor in one embodiment of the invention;

FIG. 8 shows the molecular structure of the material used in the organic photodiode in one embodiment of the invention;

FIG. 9 shows the current-voltage characteristic of the organic photodiode in one embodiment of the invention;

FIG. 10 shows the essential part of an ordinary organic photodiode;

FIG. 11 shows the cross-sectional view of the essential part of an ordinary bulk hetero-junction type organic photodiode;

FIG. 12 shows the configuration of an image sensor;

FIG. 13 is a diagram showing the organic diode in one embodiment of the invention;

FIG. 14 is a diagram showing the organic diode in one example of the invention;

FIG. 15 is a diagram showing the organic diode in one example of the invention;

FIG. 16 shows the molecular structure of the material used in the organic diode in one example of the invention;

FIG. 17 shows the current-voltage characteristic of the organic diode in one example of the invention;

FIG. 18 shows the basic configuration of a conventional organic diode; and

FIG. 19 shows the basic configuration of a conventional bulk hetero-junction type organic diode.

### DETAILED DESCRIPTION OF THE PREFERRED EMBODIMENTS

The organic photoelectric conversion element of the invention is characterized by comprising at least a pair of electrodes, a photoelectric conversion region arranged between the electrodes and containing at least an electron donating organic material and an electron accepting material, and a buffer layer made of at least one inorganic matter and arranged between the photoelectric conversion region and at least one of the pair of the electrodes.

Although the reason is not clear, according to the above-described constitution, it was possible to stabilize the performance of the element thus leading to reliability enhancement by inserting the buffer layer. Such advantages are considered to be due to the following reason, though it is just a presumption.

In an organic photoelectric conversion element, a photo-electromotive force generates by the formation of excitons with the light energy supplied to the photoelectric conversion layer due to light absorption and by the transfer of the excited electrons between materials. Since the electromotive force thus generated is usually very small with a level of 1.0 V or less, and the generated current is also small, the generated electrons cannot reach the electrode when the series resistance in the element is high, and the electromotive force cannot be taken out. To reduce the serial resistance, measures are adopted so as to make the contact between the constituent materials ohmic. But, another important factor is the physical contact between the constituent materials. A buffer layer is considered to contribute to the improvement of the adhesion at these contact planes, and achieve a long life organic photoelectric conversion element by maintaining the contact condition stable over an extended period of time.

Moreover, it is also considered possible to suppress the deterioration of the constituent materials. In an ordinary solid thin film-type organic photoelectric conversion element, a PEDOT:PSS (a mixture of polythiophene with polystyrenesulfonic acid) layer is used for the purpose of conversion efficiency enhancement. This PEDOT:PSS layer, which is effective for the improvement of initial performance, has a problem on the stability over an extended period of time. In particular, when reduced, the layer forms an ionic ingredient, which causes the deterioration of the other constituent materials such as the organic semiconductor material. Since the buffer layer suppresses such reduction of the PEDOT:PSS layer, and further reduces the diffusion of the ionic ingredient, the layer is considered to be able to realize a long life organic photoelectric conversion element.

Further, in the organic photoelectric conversion element of the invention, the buffer layer contains an oxide. As has been described above, an organic thin film, particularly the PEDOT:PSS layer, has a feature vulnerable to reduction. But, since the layer is now connected to the photoelectric conversion region via the oxide, the PEDOT:PSS layer becomes more resistant to reduction, thus achieving a longer life.

Moreover, in the organic photoelectric conversion element of the invention, the buffer layer contains a transient metal oxide.

And, the organic photoelectric conversion element of the invention includes one in which the buffer layer comprises the oxide of molybdenum or vanadium.

Meanwhile, the oxide to be used here includes, in addition to the oxide of vanadium and the oxide of molybdenum, the oxides of chromium (Cr), tungsten (W), niobium (Nb), tantalum (Ta), titanium (Ti), zirconium (Zr), hafnium (Hf), scandium (Sc), yttrium (Y), thorium (Tr), manganese (Mn), iron (Fe), ruthenium (Ru), osmium (Os), cobalt (Co), nickel (Ni), copper (Cu), zinc (Zn), cadmium (Cd), aluminum (Al), gallium (Ga), indium (In), silicon (Si), germanium (Ge), tin (Sn), lead (Pb), antimony (Sb), bismuth (Bi), and the oxides of so-called rare earth elements from lanthanum (La) to lutetium (Lu). Among these, aluminum oxide (AlO), copper oxide (CuO) and silicon oxide (SiO) are particularly effective for life expansion.

As shown above, the buffer layer can use a suitable compound via selection from the oxide or nitride of a transient metal represented by molybdenum and vanadium.

For example, a transient metal compound, which takes a plural number of oxidation values, can assume plural potential levels, thus making easy the charge extraction from an organic semiconductor layer as a photoelectric conversion layer. Thus, it is considered that not only stabilization can be attained but also charge generation efficiency can be enhanced.

Further, in the organic photoelectric conversion element of the invention, the buffer layer contains a nitride.

Nitrides are stable and, in addition to the effect of adhesion enhancement, suppress the reduction of the PEDOT:PSS layer, and thus can realize further life expansion.

Moreover, in the organic photoelectric conversion element of the invention, the buffer layer contains a transient metal nitride.

There are a large number of kinds for nitrides, most of which are in use as functional materials. They can be mainly fabricated into the form of film by sputtering or CVD process. A variety of compounds are known ranging from those used as semiconductors to highly insulating materials. As a result of various experiments, it was found that, with a highly insulating compound, charge can be taken out by making the film thickness roughly 5 nm or less in the film-forming step. Specific compounds include the following ones, among which titanium nitride (TiN) is preferred. TiN is known as a very hard material showing a stability against heat.

In addition to TiN, gallium nitride (GaN), indium nitride (InN), aluminum nitride (AIN), boron nitride (BN), silicon nitride (SiN), magnesium nitride (MgN), molybdenum nitride (MoN), calcium nitride (CaN), niobium nitride (NbN), tantalum nitride (TaN), vanadium nitride (BaN), zinc nitride (ZnN), zirconium nitride (ZrN), iron nitride (FeN), copper nitride (CuN), barium nitride (BaN), lanthanum nitride (LaN), chromium nitride (CrN), yttrium nitride (YN), lithium nitride (LiN), titanium nitride (TiN) and complex nitrides of these can be used.

And, in the organic photoelectric conversion element of the invention, the buffer layer contains an oxy-nitride. Oxy-nitrides are highly resistant to oxygen, and provide a close and highly reliable film, thus capable of stably maintaining the interface.

Further, in the organic photoelectric conversion element of the invention, the buffer layer contains a transient metal oxy-nitride.

For example, the oxy-nitride crystal of ruthenium (Ru) Ru₄Si₂O₇N₂, which has an extremely high heat-resistance (1500° C.), is applicable as the buffer layer by fabricating into the form of thin film, whereby, after film formation by the sol-gel process, heat treatment is conducted to give a final film.

Otherwise, oxy-nitrides such as the sialons of the IA, IIA and IIIA group metals including barium sialon (BaSiAlON), calcium sialon (CaSiAlON), cerium sialon (CeSiAlON), lithium sialon (LiSiAlON), magnesium sialon (MgSiAlON), scandium sialon (ScSiAlON), yttrium sialon (YSiAlON), erbium sialon (ErSiAlON) and neodium sialon (NdSiAlON), and multi-metal sialons can be applied. Thin films of these materials can be formed by CVD process or sputtering process. In addition, lanthanum nitride silicate (LaSiON), lanthanum europeum nitride silicate (LaEuSi₂O₂N₃) and silicon oxynitride (SiON₃) are also applicable. Since most of these are usually insulators, the film thickness must be made as thin as roughly 1 nm to 5 nm.

Moreover, in the organic photoelectric conversion element of the present invention, the buffer layer contains the complex oxide of transient metals.

Though the reason is not clear, a stable characteristic is attained by using the complex oxide of transient metals for the buffer layer.

There are a large number of complex oxides, among which many have electronically interesting properties. Specifically, the following compounds can be mentioned.

For example, in addition to barium titanate (BaTiO₃) and strontium titanate (SrTiO₃),calcium titanate (CaTiO₃), potassium niobate (KnbO₃), bismuth iron oxide (BiFeO₃), lithium niobate (LiNbO₃), sodium vanadate (Na₃VO₄), Iron vanadate (FeVO₃), vanadium titanate (TiVO₃), vanadium chromate (CrVO₃), nickel vanadate (NiVO₃), magnesium vanadate (MgVO₃), calcium vanadate (CaVO₃), lanthanum vanadate (LaVO₃), vanadium molybdate (VMoO₅), vanadium molybdate (V₂MoO₅), lithium vanadate (LiV₂O₅), magnesium silicate (Mg₂SiO₄), magnesium silicate (MgSiO₃), zirconium titanate (ZrTiO₄), strontium titanate (SrTiO₃), lead magnesate (PbMgO₃), lead niobate (PbNbO₃), barium borate (BaB₂O₄), lathanum chromate (LaCrO₃), lithium titanate (LiTi₂O₄), lanthanum cuprate (LaCuO₄), zinc titanate (ZnTiO₃) and calcium tangstate (CaWO₄) can be used.

The invention can be practiced by using any of these, but preferably barium titanate (BaTiO₃) can be cited as an example. BaTiO₃, which is a representative dielectric complex oxide with a highly insulating property, has been found to be able to take out electric charge in the case where it is used as a thin film. Since BaTiO₃ and strontium titanate (SrTiO₃) are stable as compounds and have vary large dielectric constants, effective charge taking out is possible. Sputtering, sol-gel or CVD process may be appropriately selected for film formation.

Meanwhile, some of the above-cited compounds can take different valence values, and such compounds with valence values different from those cited above are also included in the scope of the invention.

The organic photoelectric conversion element of the invention comprises an electrode formed on a substrate, a PEDOT:PSS layer formed on the electrode, a buffer layer formed on the PEDOT:PSS layer and containing an inorganic film, an organic semiconductor layer, and an electrode formed on the organic semiconductor layer.

According to this configuration, a stable photoelectric conversion element that consistently exhibits a high efficiency over a long period of time can be provided owing to the buffer layer containing an inorganic film inserted at the interface between the PEDOT:PSS layer and the photoelectric conversion layer wherein the buffer layer suppresses the phase separation in the PEDOT:PSS layer thus maintaining a stable charge transport property.

Such preferable result is considered to be due to the following mechanism. The PEDOT:PSS layer, which can be easily fabricated into a film by spin coating and the like contributes to the increase of electromotive force when inserted between an electrode and a photoelectric conversion layer, is a de facto standard material for charge transport layers.

However, as mentioned previously, the PEDOT:PSS layer is made of a mixture of two polymer materials, polystyrenesulfonic acid and polythiophene wherein the former is ionic and the latter has polarity localized in the polymer chain. Due to a coulomb interaction caused by the charge anisotropy, the two polymers are mildly bonded, thus exhibiting an excellent carrier (charge) transport nature.

For the PEDOT:PSS layer to exhibit an excellent property, the intimate interaction between the two components are indispensable; but, generally speaking, a high polymer mixture is liable to undergo phase separation due to a delicate difference in the solubility in a solvent. This general trend also holds for the PEDOT:PSS layer. Ready phase separation means that the mild bonding of two polymers will readily come off, showing the possibility that the PEDOT:PSS layer unstably behaves during operation, and that the component not contributing to the bonding, particularly an ionic component, diffuses by the internal electric field caused by light irradiation to exert an undesirable action on the other functional layers as a result of phase separation. As has been described heretofore, the PEDOT:PSS layer is not stable at all in spite of its excellent charge transport nature.

But, by inserting a buffer layer at the interface between the PEDOT:PSS layer and a photoelectric conversion layer, the phase separation of PEDOT is suppressed, resulting in stable maintenance of charge transport nature.

In the organic photoelectric conversion element of the invention, the photoelectric conversion region contains an electron donating layer having an electron donating organic material and an electron accepting layer having an electron accepting material.

The organic photoelectric conversion element of the invention includes one in which the buffer layer intervenes between the electron donating layer and the electrode.

The organic photoelectric conversion element of the invention includes a configuration in which the buffer layer intervenes between the electron accepting layer and the electrode.

The organic photoelectric conversion element of the invention includes a configuration wherein the photoelectric conversion region contains an organic semiconductor layer in which an electron donating organic material and an electron accepting material are dispersed.

The method of producing the organic photoelectric conversion element of the invention comprises a step of forming an electrode, a step of forming a buffer region containing an inorganic matter, a step of forming an organic photoelectric conversion region on the buffer region, and a step of forming an electrode on the organic photoelectric conversion region.

With such a configuration, a long life organic photoelectric conversion element can be provided only by adding the step of forming a buffer layer.

Further, in the method of producing the organic photoelectric conversion element of the present invention, the step of forming a buffer region contains the step of forming a buffer layer by a wet process on the electrode.

With such a configuration, the inorganic film is formed into film by a sol-gel process. Thus, the element can be easily produced without resorting to a vacuum process.

Since, in the invention, at least one electrode is arranged so as to be in contact with the organic semiconductor layer via the buffer layer comprising an inorganic material, performance deterioration after element production can be suppressed, thus providing a long life organic photoelectric conversion element.

### EMBODIMENT 1

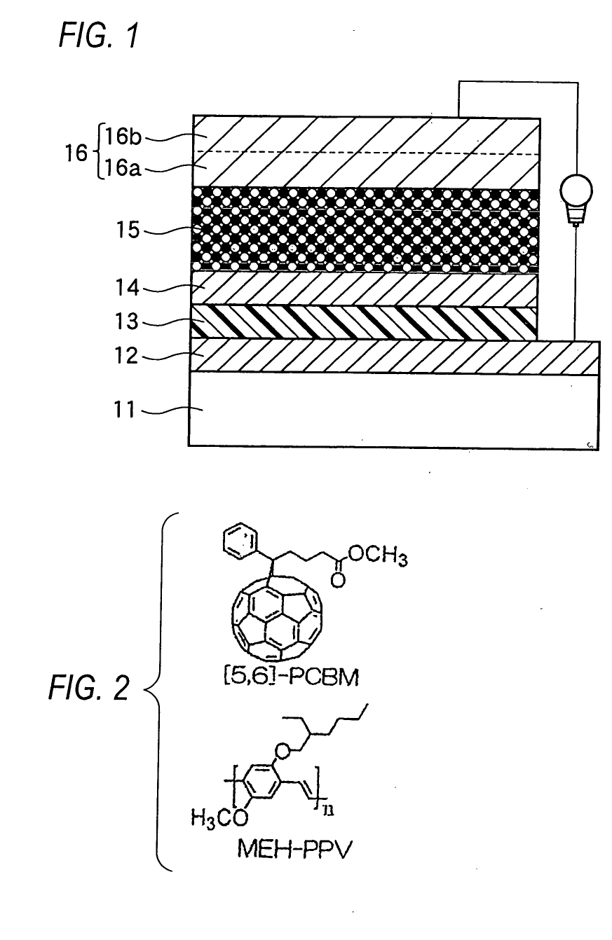

One embodiment of the invention is described in detail with reference to the drawings. The present embodiment is characterized by that a buffer layer 14 comprising an inorganic film made of molybdenum oxide (MoO₃) is arranged between an organic photoelectric conversion layer 15 and a positive electrode 12, as shown in FIG. 1.

Namely, as shown in FIG. 1, the buffer layer 14 comprising an inorganic matter is inserted between the charge transport layer 13 and the organic photoelectric conversion layer 15 for the purpose of preventing the diffusion of the materials constituting the charge transport layer 13, particularly ionic materials into the organic photoelectric conversion layer 15. Thus, on a substrate 11, a positive electrode 12, a charge transport layer 13, a buffer layer 14, an organic photoelectric conversion layer 15 and a negative electrode 16 are stacked in this order.

With this configuration, an organic photoelectric conversion element showing high efficiency and stabilized performance can be obtained. Such achievements of high efficiency and performance stabilization are considered to be due to the following reasons.

In this organic photoelectric conversion element, the charge transport layer 13 comprising a mixture of an ionic substance and a polar substance is arranged in order to minimize the recombination probability of excitons generated with a high charge transport efficiency.

For this charge transport layer 13 to exhibit an excellent charge transport capability, a mild bonding of the ionic substance with the polar one is indispensable. But, generally, a mixture of polymer materials is liable to undergo phase separation due to a delicate difference in the solubility in a solvent, and once phase separation occurs, the mild bonding between the two polymers comes off comparatively easily. Thus, if the bonding is unstable or the amount of the component not participating in the bonding is large as a result of phase separation, the expected transport capability cannot be demonstrated.

In particular, once the ionic substance diffuses into the organic photoelectric conversion layer by heat or the internal electric field, it is predicted that the compositional ratios in the charge transport layer vary to deteriorate transport efficiency, that the diffused component gives an adverse effect on the exciton-generating efficiency itself or act as carrier traps. Since such diffusion depends on the use conditions such as time and temperature, the performance is considered to become unstable.

By arranging the buffer layer containing a stable inorganic matter, the diffusion of the ionic material is prevented, leading to performance stabilization.

Meanwhile, as the buffer layer 14, molybdenum oxide or the oxide or nitride of various transient metals such as vanadium, copper, nickel, ruthenium, titanium, zirconium, yttrium and lanthanum can be used.

As the substrate 11, glass is usually used. But to make use of the flexibility of organic materials, flexible materials such as plastic films may be used, too. Further, various polymer materials including poly(ethylene terephthalate), polycarbonate, poly(methyl methacrylate), polyether sulfone, poly(vinyl fluoride), polypropylene, polyethylene, polyacrylate, an amorphous polyolefin, and a fluorine-containing resin, and substrates made of a compound semiconductor such as silicon wafer, gallium arsenide and gallium nitride are applicable.

As the positive electrode 12, ITO (indium tin oxide), ATO (Sb-doped SnO₂) and AZO (Al-doped ZnO) can be adopted. As the negative electrode 17, metal materials such as Al, Ag and Au can be adopted. With such configuration, as the material for the positive electrode 12 is transparent to light, the light from the substrate 11 can be incident on the organic photoelectric conversion layer. But, in the case where light is incident from the negative electrode 16, a certain measure need be taken such as deliberate setting of the film thickness to secure light transmittance.

The negative electrode 16 is formed in a double-layer structure comprising an metal electrode 16b made of, for example, aluminum, and a layer 16a which acts to improve the efficiency of taking out the electrons at the negative electrode side. For this layer 16a, an inorganic dielectric thin film, a metal fluoride or oxide such as LiF can be used. By way of precaution, this layer 16a is not essential for the invention, but may be used depending on the requirement.

As the charge transport layer 13 at the positive electrode side, a PEDOT:PSS layer (a mixture of polythiophene and polystyrenesulfonic acid) is applicable. And, further life expansion is possible by using an inorganic matter such as a multi-valent oxide including MoO₅ instead of PEDOT, as the charge transport layer.

The organic photoelectric conversion layer 15 contains an electron donating organic material and an electron accepting material.

As the electron donating organic material, phenylenevinylenes such as methoxy-ethylhexoxy-polyphenylenevinylene (MEH-PPV), polymers which have the various derivatives of fluorene, carbazole, indole, pyrene, pyrrole, picoline, thiophene, acetylene and diacetylene as a recurring unit or copolymers of these with another monomer, derivatives of such polymers and copolymers, and a group of polymer materials which are given the generic name of dendolymer can be used.

Moreover, the material is not restricted to polymers, but porphyrin compounds such as, for example, porphine, copper tetraphenylporphine, phthalocyanine, copper phthalocyanine, and titanium phthalocyanine oxide; aromatic tertiary amines such as 1,1-bis[4-(di-p-tolylamino)phenyl]cyclohexane, 4,4′,4″-trimethyltriphenylamine, N,N,N′,N′-tetraquis(p-tolyl)-p-phenylenediamine, 1-(N,N-di-p-tolylamino)naphthalene, 4,4′-bis(dimethylamino)-2-2′-dimethyltriphenylmethane, N,N,N′,N′-tetraphenyl-4,4′-diaminobiphenyl, N,N′-diphenyl-N,N′-di-m-tolyl-4,4′-diaminobiphenyl, and N-phenylcarbzole; stilbene compounds such as 4-di-p-tolylaminostilbene, and 4-(di-p-tolylamino)-4′-[4-(di-p-tolylamino)styryl]stilbene; triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, silazane derivatives, polysilane-based aniline copolymers, oligomers, styrylamine compounds, aromatic dimethylidyne-based compounds, and poly(3-methylthiophene) can also be used.

As the electron accepting material, fullerene compounds represented by C60 and C70, carbon nano-tubes and their derivatives, oxadiazole derivatives such as 1,3-bis(4-tert-butylphenyl-1,3,4-oxadiazolyl)phenylene (OXD-7), anthraquinodimethane derivatives, and diphenylquinone derivatives can be used.

By way of precaution, the material for the organic photoelectric conversion layer 15 is not limited to those enumerated above, but the layer may contain, for example, a material acting as an electron acceptor such as those having a functional group including acrylic acid, acetamide, dimethylamino group, a cyano group, a carboxyl group and a nitro group, a material such as benzoquinone derivatives, tetracyanoethylene and tetracyanoquinodimethane and their derivatives that accepts electron, or a material acting as an electron donor such as, for example, those having a functional group such as amino, triphenyl, alkyl, hydroxyl, alkoxy and phenyl, a substituted amine compounds such as phenylenediamine, anthracene, benzoanthracene, substituted benzoanthracene compounds, pyrene, substituted pyrene, carbazole and its derivatives, and tetrathiafulvalene and its derivatives, and may be subjected to so-called doping treatment.

Meanwhile, doping means introducing an electron accepting molecule (acceptor) or an electron-donating molecule (donor) as a dopant in an organic semiconductor film.

Accordingly, an organic semiconductor film subjected to doping is one containing the aforementioned condensed polycyclic aromatic compound and a dopant. The dopant used in the invention may be an acceptor or a donor. As the acceptor, halogens such as Cl₂, Br₂, I₂, ICl, ICl₃, IBr and IF, Lewis acids such as PF₅, AsF₅, SbF₅, BF₃, BCl₃, BBr₃ and SO₃, protonic acids such as HF, HCl, HNO₃, H₂SO₄, HClO₄, FSO₃H, ClSO₃H and CF₃SO₃H, organic acids such as acetic acid, formic acid and aminoacid, transient metal compounds such as FeCl₃, FeOCl, TiCl₄, ZrCl₄, HfCl₄, NbF₅, NbCl₅, TaCl₅ MOCl₅, WF₅, WCl₆, UF₆, LnCl₃ (Ln=a lanthanoid such as La, Ce, Nd and Pr, and Y), electrolytic anions such as Cl⁻, Br⁻, I⁻, ClO₄⁻, PF₆⁻, AsF₅⁻, SbF₆⁻, BF₄ and sulfonic acid anion are mentioned. On the other hand, as the donor, alkali metals such as Li, Na, K, Rb and Cs, alkaline earth metals such as Ca, Sr and Ba, rare earth metals such as Y, La, Ce, Pr, Nd, Sm, Eu, Gd, Th, Dy, Ho, Er and Yb, ammonium ion, R₄P⁺, R₄As⁺, R₃S+ and acetylcholine are mentioned.

As the method of introducing these dopants, one in which the organic semiconductor layer is formed in advance, followed by the incorporation of a dopant, and another one in which a dopant is incorporated at the time of the film formation of the organic semiconductor layer can be adopted. As the former doping method, gas phase doping using a dopant in a gaseous state, liquid phase doping in which a dopant in a solution or liquid state is brought into contact with the thin film to cause doping and solid phase doping in which a dopant in a solid state is brought into contact with the thin film to promote diffusion doping are mentioned. And, in liquid phase doping, the doping efficiency can be controlled by conducting an electrolytic treatment whereby the dopant concentration can be regulated. As the latter method, a solution or dispersion of a mixture comprising an organic semiconductor compound and a dopant may be simultaneously coated and dried. For example, in the case where vacuum vapor deposition process is employed, a dopant can be incorporated by co-vapor depositing an organic semiconductor compound and the dopant. In addition, in the case where a thin film is fabricated by sputtering, a dopant can be incorporated in the thin film by using dual targets of an organic semiconductor and the dopant for sputtering.

As the method of forming such an organic semiconductor film, vacuum vapor deposition, molecular beam epitaxial growth process, ion cluster beam process, low energy ion beam process, ion plating process, CVD process, sputtering process, plasma polymerization process, electrolytic polymerization process, chemical polymerization process, spray coating, spin coating, blade coating, dip coating, casting method, roll coating, bar coating, die coating and LB process are mentioned. These methods can be adopted depending on the material to be used. However, from productivity viewpoint, spin coating, blade coating, dip coating, roll coating, bar coating and die coating are preferred whereby a thin film can be simply and precisely formed by using an organic semiconductor solution. The thickness of the thin film comprising any one of these organic semiconductors is not specifically limited, but the characteristics of the resulting photoelectric conversion element is strongly influenced by the thickness of the organic semiconductor film quite often. And the film thickness is preferably 1 μm or less and in particular 10 to 300 nm, depending on the type of the organic semiconductor.

In the meantime, as the buffer layer, in addition to the above-cited materials, the oxide of molybdenum, the oxide or nitride of chromium, tungsten, vanadium, niobium, tantalum, titanium, zirconium, hafnium, scandium, yttrium, so-called rare earth elements including from lanthanum to lutetium, thorium, manganese, iron, ruthenium, osmium, cobalt, nickel, copper, zinc, cadmium, aluminum, gallium, indium, silicon, germanium, tin, lead, antimony or bismuth, further the complex oxide or nitride comprising two or more of these elements or the complex oxide or nitride comprising one of these elements and an alkali and alkaline earth metal are mentioned.

The buffer layer using these materials can be formed by the generally used, thin film-forming method including vacuum vapor deposition based on resistive heating, electron beam vapor deposition, sputtering, CVD and PVD.

With respect to the film thickness, the most appropriate value should be chosen depending on the material to be used. Generally speaking, the range of from 1 nm to 1 μm is preferred. For example, in the case of the oxide of molybdenum, the range of from 3 nm to 100 nm is preferred.

When the film thickness of the buffer layer is too small, it is difficult to prepare a homogeneous thin film. On the contrary, too large a film thickness is not desirable because the electric resistance becomes undesirably high, leading to the efficiency of taking out carriers to decrease, and because the uniformity of the film deteriorates.

The material and film thickness of the buffer layer is appropriately determined by the performance expected to the organic photoelectric conversion element.

As the negative electrode, an electro-conductive thin film made of a metal is generally used; for example, metals such as gold, copper, aluminum, platinum, chromium, palladium, indium, nickel, magnesium, silver and gallium, alloys of these metals, tin oxide and indium oxide, polysilicon, amorphous silicon, oxide semiconductors such as the oxide of tin, indium oxide and titanium oxide, and compound semiconductors such as gallium arsenide and gallium nitride can be applied.

### EXAMPLE 1

Next, an example is described. First of all, on a glass substrate 11, an ITO film 12 with 150 nm thickness was formed by means of sputtering. Thereafter, on this ITO film a resist film with 5 μm thickness was provided by spin-coating a resist material (OFPR-800 of Tokyo Ohka Kogyo Co., Ltd.). Then, via masking, exposure and development, the resist film was patterned into the shape of a positive electrode 12.

Then, after immersed in an 18 N aqueous hydrochloric acid kept at 60° C. to etch the ITO film 12 at the portion where no resist film is present, this glass substrate was washed with water. Finally, by removing the resist film, a positive electrode 12 consisting of the ITO film in the pre-determined pattern was obtained.

Then, the glass substrate 11 was subjected to ultrasonic rinsing with a detergent (Semico-clean, a product of Furuuchi Chemical Corp.) for 5 min, ultrasonic rinsing with pure water for 10 min, ultrasonic rinsing for 5 min with a solution obtained by mixing 1 part (by volume) of aqueous hydrogen peroxide and 5 parts of water with 1 part of aqueous ammonia, and ultrasonic rinsing with 70° C. purified water for 5 min successively in this order. Thereafter, the water adhering the glass substrate 11 was removed with use of a nitrogen blower, and further heating to 250° C. dried the substrate.

In succession, an aqueous solution of poly(3,4)ethylenedioxythiophene/polystyrenesulfonate (PEDT/PSS) was placed dropwise through a 0.45 μm pore size filter on the glass substrate 11 thus prepared so as to have the ITO film 12, and uniformly spread by spin-coating. By heating the coated product in a clean oven kept at 200° C. for 10 min, a charge transport layer 13 with 60 nm thickness was formed.

Then, the glass substrate 11 on which the charge transport layer 13 was formed in such a manner was placed in a resistive heating-type vapor deposition apparatus. And a buffer layer 14 with 5 nm thickness was formed by vapor-depositing molybdenum oxide after the pressure inside the apparatus was reduced to the degree of vacuum of 0.27 mPa (=2×10⁻⁶ Torr) or less.

And, after a chlorobenzene solution comprising poly(2-methoxy-5-(2′-ethylhexyloxy)-1,4-phenylenevinylene) (MEH-PPV), which has the molecular structure as shown in FIG. 2 and functions as an electron donating organic material, and [5,6]-phenyl C61 butyric acid methyl ester ([5,6]-PCBM) with a mixing ratio of 1:4 in weight was spin-coated, the coated product was subjected to heat treatment in a clean oven kept at 100° C. for 30 min to provide an about 100 nm thick organic photoelectric conversion layer 15.

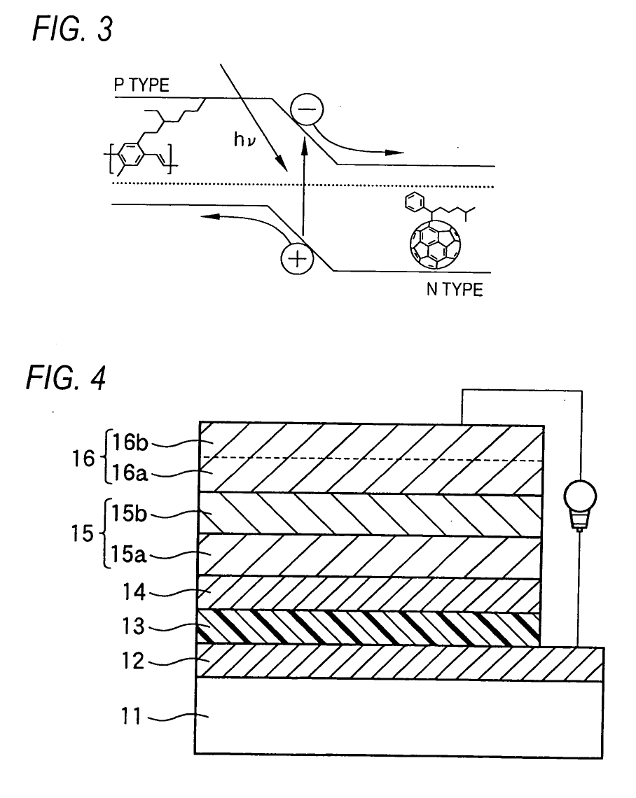

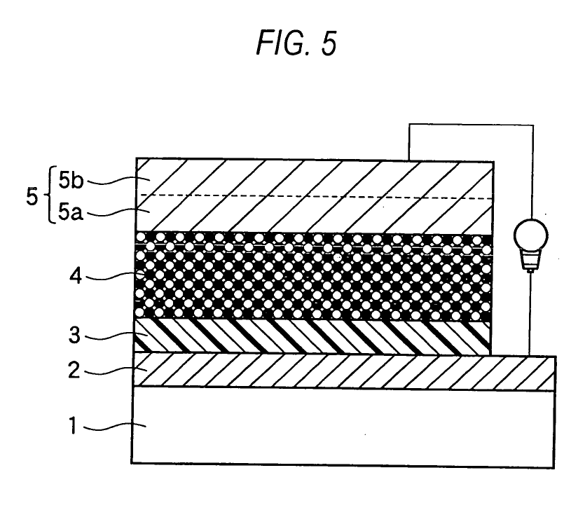

In the meantime, MEH-PPV is a p-type organic semiconductor, while [5,6]-PCBM is an n-type organic semiconductor. The electrons of the excitons generated by light adsorption diffuse through the conduction band shown in FIG. 3 to be transferred to [5,6]-PCBM, while the holes diffuse through the valence band to be transferred to MEH-PPV These electrons and holes are transported to the negative electrode 16 and the positive electrode 12 via these molecules, respectively.

This [5,6]-PCBM is a modified fullerene compound having an extremely large electron mobility. In addition, since this compound can be used as the mixture with MEH-PPV which is an electron donating material, separation and transport of electron-hole pairs can be effectively achieved, thus showing the advantages of high photoelectric efficiency and low production cost.

Finally, on this organic photoelectric conversion layer, LiF was deposited in the form of an about 1 nm thick film, and then in succession Al was deposited in the form of an about 10 nm thick film in the resistive heating-type vapor deposition apparatus, whose pressure had been reduced to the degree of vacuum of 0.27 mPa (=2×10⁻⁶ Torr) or less, to provide a negative electrode 16.

Thereafter, a passivation layer not shown in the drawing was formed on the negative electrode to give an organic photoelectric conversion element.

The organic photoelectric conversion element having such a configuration exhibits a longer life with stable characteristics under a variety of environments including elevated temperature conditions compared with a conventional organic photoelectric conversion element free of the buffer layer 14.

### EMBODIMENT 2

Next, Embodiment 2 for practicing the invention is described. While, in the foregoing Embodiment 1, the organic photoelectric conversion layer consisted of a mono-layer containing an electron donating material and an electron accepting material, the present embodiment adopts a dual-layer structure comprising an electron accepting layer 15 a and an electron donating layer 15b as shown in FIG. 4 wherein a pn junction is formed at the interface of the two layers. The other portions are structurally the same as those of the organic photoelectric conversion element set forth in the aforementioned Embodiment 1.

In the organic photoelectric conversion element of such a structure, the transfer of carriers is limited to occur only at the pn junction. Therefore, the excitons generated in the inside of the electron donating layer far from the junction cannot deliver electrons to the electron accepting material. Hence, such a phenomenon may exert an adverse effect on the PEDOT:PSS layer and the other layers, but the adverse effect is suppressed by the introduction of the buffer layer, thus achieving stabilization of the characteristics as well as life expansion of the organic photoelectric conversion element.

By way of precaution, the buffer layer need not always be inserted between the electron donating layer and an electrode, but may be inserted between the electron accepting layer and an electrode, whereby an extended life of the element can be attained, too.

### EXAMPLE 2

Now, Example 2 is described. In the same manner as in Example 1, a positive electrode 12 comprising a pre-determined pattern of ITO film was provided on a glass substrate 11 by sputtering.

Then, the glass substrate 11 was heated for drying after rinsing, and a charge transport layer 13 comprising a poly(3,4)ethylenedioxythiophene/polystyrenesulfonate, PEDOT:PSS layer was formed on this substrate 11.

Next, this substrate 11 was placed in a resistive heating-type vapor deposition apparatus, and vapor deposited with molybdenum oxide under a reduced pressure condition of 0.27 mPa (=2×10⁻⁶ Torr) so as to give a 5 nm thick buffer layer 14.

Then, an electron donating organic material layer 15a comprising a polymer layer containing poly(2-methoxy-5-(2′-ethylhexyloxy)-1,4-phenylenevinylene) (MEH-PPV) was formed by spin coating, and an electron accepting material layer 15b comprising fullerene (C60) was formed by vacuum deposition, respectively, to provide an about 100 nm thick organic photoelectric conversion layer 15.

Meanwhile, MEH-PPV is a p-type organic semiconductor, while C60 is an n-type organic semiconductor. The electrons of the excitons generated by light adsorption diffuse through the conduction band shown in FIG. 3 to be transferred to C60, while the holes diffuse through the valence band to be transferred to mEH-PPV. These electrons and holes are transported to the negative electrode 16 and the positive electrode 12 via these molecules, respectively.

This C60, having an extremely large electron mobility, can effectively perform the separation and transport of electron/hole pairs.

Finally, as in Example 1, on this organic photoelectric conversion layer, LiF was deposited in the form of an about 1 nm thick film, and then in succession Al was deposited in the form of an about 10 nm thick film to give a negative electrode 16.

Thereafter, a passivation layer not shown in the drawing was formed on the negative electrode to give an organic photoelectric conversion element.

The organic photoelectric conversion element of such a configuration exhibits stable performance and a long life.

In the foregoing example, explanation was given on the structure wherein a PEDOT:PSS layer was used as the charge transport layer. But, by using an inorganic material instead of the PEDOT:PSS layer, or by arranging only a buffer layer consisting of an inorganic matter between the photoelectric conversion layer and an electrode, unstable factors are excluded, thus achieving still further stabilization.

According to the invention, the element stably operates without showing any deterioration of photoelectric conversion efficiency even when driven for a long time, and can be used under a variety of environments including elevated temperature conditions. Thus, it is applicable to solar cells, image sensors and photo-sensor.

The organic photodiode of the present invention will be described. It is provided an organic photodiode comprising at least a pair of electrodes, and a photoelectric conversion region provided between the electrodes and containing at least an electron donating material and at least an electron accepting material mixed together, and a carbon layer arranged between the photoelectric conversion region and at least one of the pair of electrodes, and is configured so that charge accumulation is possible. By introducing the carbon layer, the dark current of a BH-type photodiode in which the electron donating material and the electron accepting material are mixed together can be markedly reduced. By way of precaution, the term “mixed” here indicates mixed in a liquid or solid state, and includes the film obtained by spin-coating the resultant mixture.

Further, at lets of a polyast a part of the electron donating material and the electron accepting material consismer material. Thus, not only film formation is possible by spin-coating or inkjet process with use of the materials dissolved in a variety of solvents, but also an organic photodiode excelling in thermal stability can be provided.

Further, the electron donating material and the electron accepting material entirely consist of polymer materials. Thus, not only film formation is possible by spin coating or inkjet process with use of the materials dissolved in a variety of solvents, but also an organic photodiode excelling in thermal stability can be provided.

Further, at least a part of the electron donating material and electron accepting material contains at least one compound selected from the group consisting of modified or unmodified fullerene compounds and carbon nano-tube compounds. An organic photodiode with high performance and high reliability can be provided due to excellent carrier transport capability as well as thermal stability.

Further, the carbon layer arranged in the aforementioned organic photodiode has a thickness of from 5 nm to 100 nm, preferably from 10 nm to 50 nm. As a result of the concentrated study carried out on the effect of the thickness of the carbon layer inserted in the organic photodiode, the present inventors found that a layer thickness of 5 nm or more is effective for the reduction of the dark current. But, though the effect of dark current suppression improves with the increase of the carbon layer thickness, an excessively large carbon layer thickness results in the absorption of incident light, thus adversely affecting the use efficiency of light. Therefore, a thickness not exceeding 100 nm is preferred. More preferably, by making the carbon layer thickness from 10 nm to 50 nm, an organic photodiode can be provided in which a stabilized dark current is consistent with efficient charge generation.

Furthermore, it is provided an image sensor using the aforementioned organic photodiode as the photo-receptive part, and enables to provide a highly sensitive, high S/N ratio image sensor at a low price by using an organic photodiode which has low dark current and is capable of charge accumulation.

Further, it is provided a line sensor in which the aforementioned image sensor is linearly arranged to constitute the photo-receptive part. This invention enables to provide an inexpensive image sensor used for facsimile machines, copying machines and scanners. Meanwhile, as the driving unit that transmits the output of the organic photodiodes to an external circuit, a CMOS or TFT may be arbitrarily selected depending on needs.

Further, it is provided an image sensor the photo-receptive part of which is an area sensor comprising the photo-receptive part arranged in a two-dimensional planar area form, and enables to provide an inexpensive image sensor used for digital cameras. Here again, as the driving unit that transmits the output of the organic photodiodes to an external circuit, a CMOS or TFT may be arbitrarily selected depending on needs.

Further, it is provided an image sensor in which the degree of light quantity is judged by reducing the accumulated charge with the charge generated in the organic photodiode after charge accumulation by the application of an external bias potential to the organic photodiode in advance, and enables to obtain large output voltage even when the charge amount generated by the organic photodiode is small, and to provide a highly sensitive image sensor.

In the following, the organic photodiode of the invention is described in detail.

The substrate used for the organic photodiode of the invention is not specifically limited so long as it is provided with mechanical and thermal strengths, exemplified by glass, various polymer materials including poly(ethylene terephthalate), polycarbonate, poly(methyl methacrylate), polyether sulfone, poly(vinyl fluoride), polypropylene, polyethylene, polyacrylate, an amorphous polyolefin, and a fluorine-containing resin, and metals including Al, Au, Cr, Cu, In, Mg, Ni, Si and Ti, Mg alloys such as Mg—Ag alloy and Mg—In alloy, Al alloys such as Al—Li alloy, Al—Sr alloy and Al—Ba alloy. Further, it is effective to use a flexible substrate obtained by fabricating these materials in the form of film or a composite substrate obtained by laminating two or more of substrate materials. Moreover, the substrate is not specifically restricted with respect to its electric conductivity though preferred to be insulating; within the range of not impeding the function of the organic photodiode or depending on use applications, the substrate may have electro-conductivity.

As the positive and negative electrodes of the organic photodiode, a metal oxide such as ITO, ATO (Sb-doped SnO₂) and AZO (Al-doped ZnO), a metal such as Al, Au, Cr, Cu, In, Mg, Ni, Si and Ti, magnesium alloys exemplified by Mg—Ag alloy and Mg—In alloy, and aluminum alloys exemplified by Al—Li alloy, Al—Sr alloy and Al—Ba alloy can be adopted. Moreover, by arranging an auxiliary electrode in combination, comparatively highly resistant coating-type ITO, a variety of electro-conductive polymer compounds such as PEDOT, PPV and polyfluorene can also be used.

As the electron donating organic material, polymers of phenylenevinylene, fluorene, carbazole, indole, pyrene, pyrrole, picoline, thiophene, acetylene and diacetylene, and the derivatives thereof can be used. Moreover, the material is not restricted to polymers, but porphyrin compounds such as, for example, porphine, copper tetraphenylporphine, phthalocyanine, copper phthalocyanine, and titanium phthalocyanine oxide; aromatic tertiary amines such as 1,1-bis[4-(di-p-tolylamino)phenyl]cyclohexane, 4,4′,4″-trimethyltriphenylamine, N,N,N′,N′-tetraquis(p-tolyl)-p-phenylenediamine, 1-(N,N-di-p-tolylamino)naphthalene, 4,4′-bis(dimethylamino)-2-2′-dimethyltriphenylmethane, N,N,N′,N′-tetraphenyl-4,4′-diaminobiphenyl, N,N′-diphenyl-N,N′-di-m-tolyl-4,4′-diaminobiphenyl, and N-phenylcarbzole; stilbene compounds such as 4-di-p-tolylaminostilbene, and 4-(di-p-tolylamino)-4′-[4-(di-p-tolylamino)styryl]stilbene; triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, silazane derivatives, polysilane-based aniline copolymers, oligomers, styrylamine compounds, aromatic dimethylidyne-based compounds, and poly(3-methylthiophene) can also be used.

As the electron accepting material, in addition to low molecular weight and high polymer materials similar to the aforementioned electron donating materials, fullerene compounds represented by C60 and C70, carbon nano-tubes and their derivatives, oxadiazole derivatives such as 1,3-bis(4-tert-butylphenyl-1,3,4-oxadiazolyl)phenylene (OXD-7), anthraquinodimethane derivatives, and diphenylquinone derivatives can be used.

In addition, for the improvement of short-circuit current, the techniques of introducing a metal oxide, metal fluoride or metal nitride between the organic layer and the negative electrode can preferably be adopted.

The composition and configuration of the carbon layer can be appropriately chosen. Although any type of carbon including amorphous carbon (α-C) represented by diamond-like carbon or graphite carbon may be used, those having a high specific resistance are preferably used for the purpose of the invention, i.e., the reduction of the dark current in the BH element, and amorphous carbon is particularly preferably used. Moreover, the composition of the carbon layer need not be composed of carbon alone, but carbon compounds such as carbon nitride can also be used without any trouble.

As the method of forming the aforementioned carbon layer, any one can be used so long as the method can provide a stable layer, including CVD process and sputtering. But, from the viewpoint of manufacturing cost reduction, layer formation by sputtering with use of a carbon target is preferred. The carbon target to be used, which is not specifically limited, includes isotropic graphite, anisotropic graphic and glassy carbon, among which highly purified isotropic graphite is suited. The specific resistance of the carbon layer can be arbitrarily changed depending on the type and mixing ratio of the gas for sputtering or by heat treatment after layer formation.

As the method of manufacturing the organic photodiode by using the above-enumerated materials, any of various vacuum processes such as vacuum vapor deposition and sputtering and wet processes such as spin coating and dipping process may be adopted whereby the one suited for the material and configuration to be used is selected at will. But, in consideration of the low cost characterizing the organic photodiode, a wet process, which does not require any large-scale manufacturing apparatus, is desirably adopted for the formation of the organic layers.

Next, explanation is given on a line sensor as the example of an image sensor using the organic photodiode fabricated by the above-described materials and manufacturing methods.

The image sensor of the invention is comprised of a light source for irradiating documents and the like, an optical system that guides the light reflected by the document to a photo-receptive part, an organic photodiode that outputs the light intensity in the form of voltage intensity, and a driving circuit unit that accumulates charge in the organic photodiode and acts to transmit the output of the organic photodiode to an external circuit.

In such configuration, any light source unit can be used so long as it can uniformly irradiate the document plane used for reading information, including a xenon lamp, an LED, a cool cathode ray tube, an inorganic EL and an organic EL. Among these, the organic EL is most preferred since a high luminance light emission is possible with a small size and a thin body.

Any optical system can be used so long as it can efficiently guide the information in the document plane to the photo-receptive part, and no limitation is imposed on the material and shape. However, in case where the information in the document plane must be guided to the photo-receptive part in one-to-one relationship, a selfoc lens array is desirably used.

With respect to the driving circuit unit, any type can be used so long as it can apply the pre-determined reverse bias to the organic photodiode and can detect the minute output from the organic photodiode. But, to precisely detect the output voltage of the organic photodiode, it is desirable to use a driving circuit with a far smaller input capacitance compared to the electric capacitance of the organic photodiode to be driven. Specifically, a CMOS or TFT circuit can be used, but in case of adopting a CMOS circuit, it is important to take into account the wiring capacitance in addition to the input capacitance since it is necessary to mount the CMOS circuit by means of, for example, a chip-on-glass by extending a wiring to a place remote from the photo-receptive part.

As stated heretofore, the case where the organic photodiode is used for a line sensor has been described. But, the sensor configuration is not to be limited to the one shown above; in contrast, configurations not using a light source or an optical system can be used without any trouble at all.

In the following, the best embodiments for carrying out the invention are described.

An organic photodiode in one embodiment for practicing the invention is described.

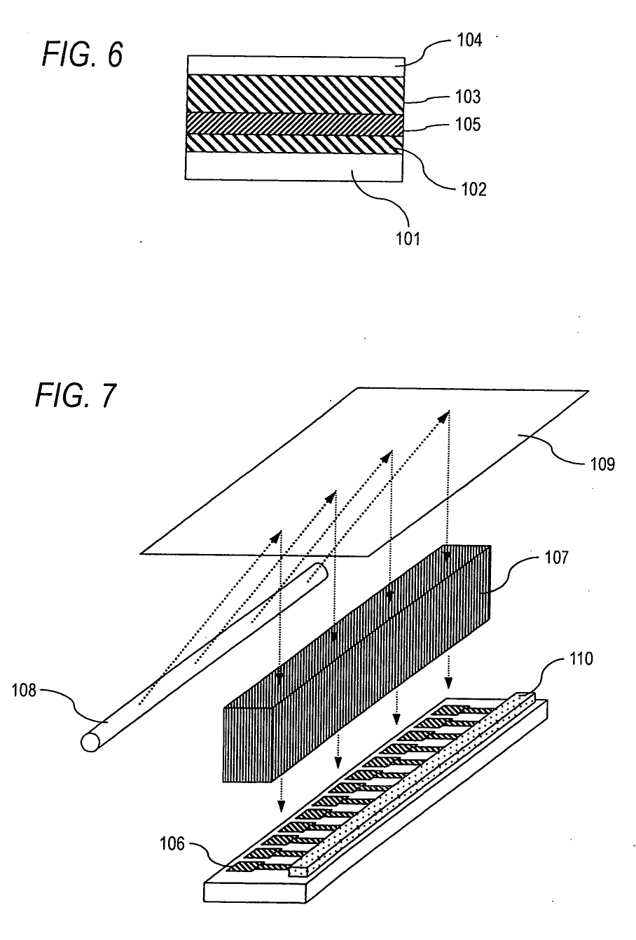

The cross-sectional view of the essential part of the organic photodiode in the present embodiment is shown in FIG. 6. The basic configuration of the element is the same as that of the conventional BH-type element, wherein a positive electrode 102, a photoelectric conversion region 103 and a negative electrode 104 are formed on a substrate 101. The point in which the organic photodiode of the invention is different from the conventional one is that a carbon layer 105 is inserted between the photoelectric conversion region and an electrode. In the present embodiment, the configuration is described in which the carbon layer is inserted between the photoelectric conversion region and the positive electrode. But, the inserted position of the carbon layer is not limited to the above one, but, for example, the carbon layer may be inserted between the photoelectric conversion region and the negative electrode, or, when a buffer layer such as a PEDOT:PSS (a mixture of polythiophene and polystyrenesulfonic acid) is used between the positive electrode and the photoelectric conversion region, between the buffer layer and an electrode, or between the buffer layer and the photoelectric conversion region without any trouble.

In the BH-type organic photodiode, a pn junction spreads throughout the entire organic layer, whereby no definite hetero-junction is formed as in the case of an inorganic diode. Therefore, the rectifying property of the diode is determined by the work function of each electrode, the carrier transport capability as well as the carrier blocking capability of the buffer layer. The polymer material called PEDOT:PSS has been used mainly as a buffer layer for a positive electrode because of its advantages of simple film formation, sparing solubility in various organic solvents enabling the ready formation of an organic thin film thereon. However, the carrier blocking capability of this material was not so high, and thus generation of a dark current when a reverse bias is applied could not be suppressed. But, according to the configuration of the invention wherein a carbon layer is arranged between an electrode and the photoelectric conversion region, not only remarkable suppression of carrier injection into the photoelectric region from the electrode under a reverse bias application is achieved, but also marked dark current reduction is possible since the photoelectric conversion region is formed on a smooth carbon layer whereby the occurrence of physical defects such as pin holes is prevented.

Moreover, due to its configuration in which an organic material as a dielectric is sandwiched between the electrodes, the organic photodiode can function as a good capacitance under reverse bias application if the dark current is suppressed whereby charge accumulation is possible.

On the other hand, the carbon layer can be formed by sputtering in an atmosphere comprising Ar gas, N₂ gas or mixtures of these. But, since the resulting carbon layer absorbs light in a broad wavelength range, when the carbon layer is inserted at the side from which light is incident on the mixture layer, the carbon layer acts to reduce the light amount reaching the mixture layer to decrease the photo-current value generated by light. For that reason, it is important to optimize the thickness of the carbon layer depending on the use application for the purpose of balancing dark current reduction with the suppression of photo-current reduction.

Next, the photoelectric conversion region is explained. As stated previously, the invention uses the mixture of an electron donating material and an electron accepting material in the photoelectric conversion region. This fact is very important for achieving a low manufacturing cost as a significant feature of the organic photodiode. The photoelectric conversion region may be formed, for example, by a dry process wherein the organic materials are simultaneously vapor deposited. But, to achieve cost reduction, adoption of a wet process such as spin coating, inkjet process and spray coating is preferred since they do not require any large-scale apparatus. Therefore, the organic photodiode of the invention uses a polymer material as at least a part of the constituent elements of the photoelectric conversion region. Since the use of a polymer material makes the viscosity control of the solution easy, the regulation of the thickness after film formation can be carried out in a simple manner, leading to an inexpensive manufacture of an organic photodiode exhibiting consistent performance. As the material to be mixed with such a polymer material, the various polymer materials and low molecular weight materials enumerated above can be appropriately used depending on use applications. For example, by formulating the photoelectric conversion region entirely only with polymer materials, formation of the film via a wet process such as spin coating can be conducted, imparting excellent thermal stability simultaneously.

Moreover, by forming the photoelectric conversion region with an electron donating polymer material together with a fullerene compound or a carbon nano-tube compound, an organic photodiode highly sensitive to light can be attained. Fullerenes and carbon nano-tube compounds, which have high electron accepting capability, are advantageously characterized by a very high photoelectric conversion efficiency even for a BH-type organic photodiode due to the capability of forming a very good pn junction with an electron donating material. To uniformly solve a fullerene compound with a polymer material together, modification of the fullerene is effective to enhance the solubility in solvents. For example, [6,6]-PCBM ([6,6]-phenyl C61-butylic acid methyl ester) is preferably adopted.

In addition, the organic photodiode of the invention, which uses organic semiconductor materials as the constituent materials thereof, has another feature of an extremely high thermal stability due to a low carrier density compared with that of inorganic semiconductor materials.

The carbon layer used in the invention can be formed by sputtering in an atmosphere comprising Ar gas, N₂ gas or mixtures of these. As the carbon, any type may be adopted so long as the specific resistance is sufficiently high, and amorphous carbon (α-C) or amorphous carbon nitride (α-CN) is preferably applied.

An organic photodiode in another embodiment practicing the invention is described. The configuration of the element is the same as the one shown in FIG. 6. In the organic photodiode of the invention, the thickness of the carbon layer is 5 nm to 100 nm, and preferably 10 nm to 50 nm. As described previously, the carbon layer is preferably formed by sputtering with use of a carbon target. The advantage of carbon layer formation by sputtering includes the facts that, since an extremely smooth carbon layer can be formed, the film quality of a mixture layer provided thereon is extremely good when the mixture layer is formed by a wet process such as spin coating or inkjet process, and that, due to the isotropic growth of the sputtered carbon layer, step coverage is high, having the effect of mitigating an electrode step difference and capable of suppressing the 2.5 shorting at an electrode edge part.

In the formation of the carbon layer by sputtering, reactive sputtering is carried out in an atmosphere of a mixed gas consisting of nitrogen or hydrogen with argon in order to control the electric resistance of the carbon layer. In such a case, when the layer thickness does not exceed 5 nm, the layer assumes an island-like structure, failing in forming a stable organic photodiode since the layer is not uniform. In contrast, when the layer is as thick as 100 nm or more, the light amount reaching the mixture layer decreases due to the light absorption of the carbon layer itself, sometimes leading to the reduction of photo-current. Therefore, a layer thickness between 5 nm and 100 nm is preferred, and, to obtain a photodiode exhibiting a large S/N ratio represented by the ratio of photo-current to dark current, a thickness between 10 nm and 50 nm is more preferred.

Meanwhile, also in the carbon layer of the present embodiment, an amorphous carbon (α-C) or amorphous carbon nitride (α-CN) layer which has been formed by sputtering in a gaseous atmosphere consisting of Ar gas, N₂ gas or the mixture of these and exhibiting a high specific resistance is preferred.

An image sensor as an embodiment practicing the invention is described.

FIG. 7 is a bird-eye view of the image sensor in an embodiment of the invention. As illustrated there, the image sensor of the invention has a photo-receptive part 106 comprising linearly arranged, plural organic photodiodes, an optical system 107 such as a selfoc lens and a light source unit 108. In this configuration, the light emitted from the light source is reflected by a document 109, impinges in the organic photodiodes through the optical system, and is converted to electric signal. Thereafter, the signal is transmitted to an external circuit by a driving circuit unit 110 comprising a CMOS circuit or TFT circuit. In such information-reading process, the intensity of light reflectance at the document plane, i.e., the density information of the document plane is transmitted to the photo-receptive part as the form of light intensity variation. And, this light intensity variation is transmitted to the outside as the intensity variation of electric signal. In such a manner, it is possible to convert the information in the document plane to electric signal.

Now, the information-reading method is described in more detail.

As described previously, high sensitivity reading is difficult by a method that instantaneously detects the photo-current variation caused by the photoelectric effect of organic photodiodes. Thus, detection of light intensity variation by an operating method called charge accumulation mode is desirable, which is carried out as follows.

As the first step, a condition is established under which the light reflected by a document is consistently incident on the organic photodiode. Then, a reverse bias is applied to the organic photodiodes to accumulate charge by putting the switch of the driving circuit unit on to connect the power supply and the organic photodiodes. In this situation, the organic photodiodes of the invention can stably accumulate charge by virtue of noticeable suppression of the dark current due to carbon layer insertion. After charge accumulation, the above-cited switch is put off to separate the power supply from the photodiode. Then, from the moment of switch off, the accumulated charge begins to decay by the photo-carrier generated by the photoelectric effect of the photodiodes. The decaying speed depends on the light intensity incident on the photodiodes, and the higher is the light intensity, the faster the charge decays. Detection of light intensity is made by reading the remaining charge as the voltage after the decay of the accumulated charge for a pre-determined time. According to this method, a large electric output is attained even if the amount of the generated photo-carriers is scarce. With the line sensor as shown in FIG. 7, such charge accumulation and charge reading are conducted in each photo-receptive part to obtain linear information.

By way of precaution, though, in the present embodiment, the explanation was given on the line sensor having linearly arranged organic photodiodes, information reading on documents or substances is possible in a similar manner with an area sensor having two-dimensionally arranged photodiodes by detecting light intensity variations.

### EXAMPLE

Now, an actual manufacturing process of an organic photodiode and the characteristics of the resulting organic photodiode are described. The constitution of the organic photodiode prepared in the present example is the same as the one shown in FIG. 6.

First of all, on a glass substrate, an ITO film 12 with 150 nm thickness was formed by means of sputtering. Thereafter on this ITO film a 5 μm thick resist film was provided by spin-coating a resist material (OFPR-800 of Tokyo Ohka Kogyo Co., Ltd.). Then, via masking, exposure and development, the resist film was patterned.

Then, after immersed in an 18 N aqueous hydrochloric acid kept at 60° C. to etch the ITO film at the portion where no resist film is present, this glass substrate was washed with water. Finally, by removing the resist film, a positive electrode consisting of the ITO film in a pre-determined pattern was obtained.

Then, the glass substrate was subjected to ultrasonic rinsing with a detergent (Semico-clean, a product of Furuuchi Chemical Corp.) for 5 min, ultrasonic rinsing with pure water for 10 min, ultrasonic rinsing for 5 min with a solution obtained by mixing 1 part (by volume) of aqueous hydrogen peroxide and 5 parts of water with 1 part of aqueous ammonia, and ultrasonic rinsing with 70° C. purified water for 5 min successively in this order. Thereafter, the water adhering the glass substrate was removed with use of a nitrogen blower, and dried by further heating to 250° C.

In succession, the glass substrate on which the positive electrode had been thus formed was placed in a sputtering apparatus. And, after the pressure of the apparatus was reduced to the degree of vacuum of 0.68 mPa (=5×10⁻⁶ Torr) or less, a carbon layer was formed. A 50 nm thick carbon layer was formed by using graphite carbon as the target and adopting the following sputtering conditions: atmospheric gas=a 50/50 mixture of argon and nitrogen, gas pressure=0.68 Pa (=5×10⁻³ Torr), DC power=300 W, and sputtering time=3 min.

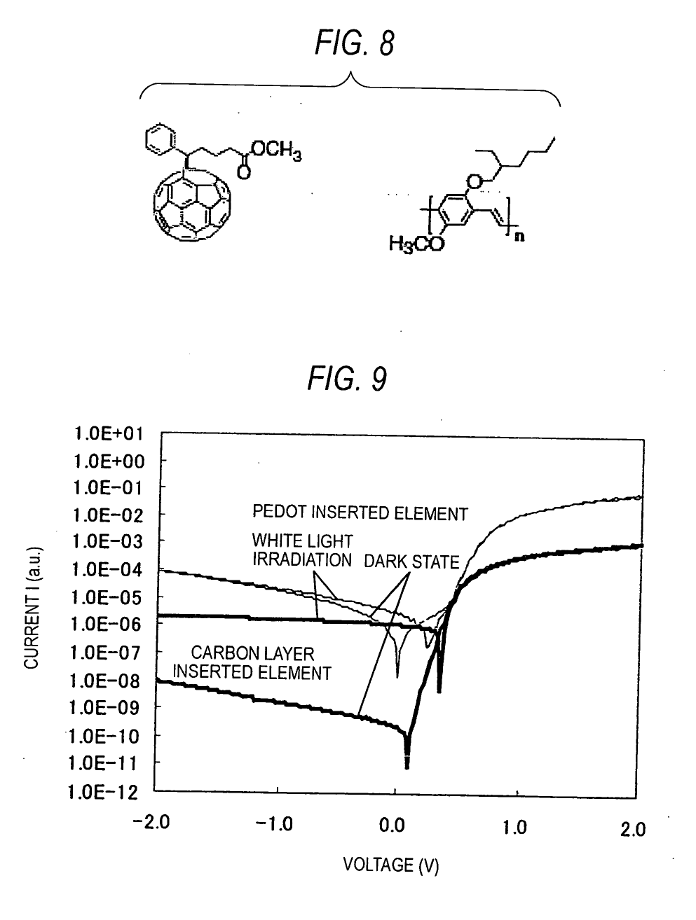

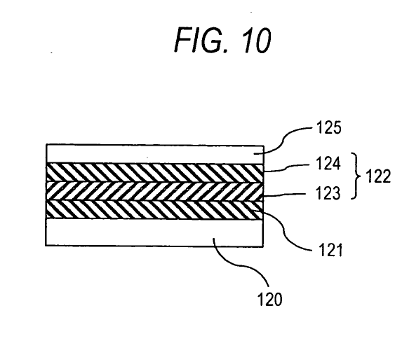

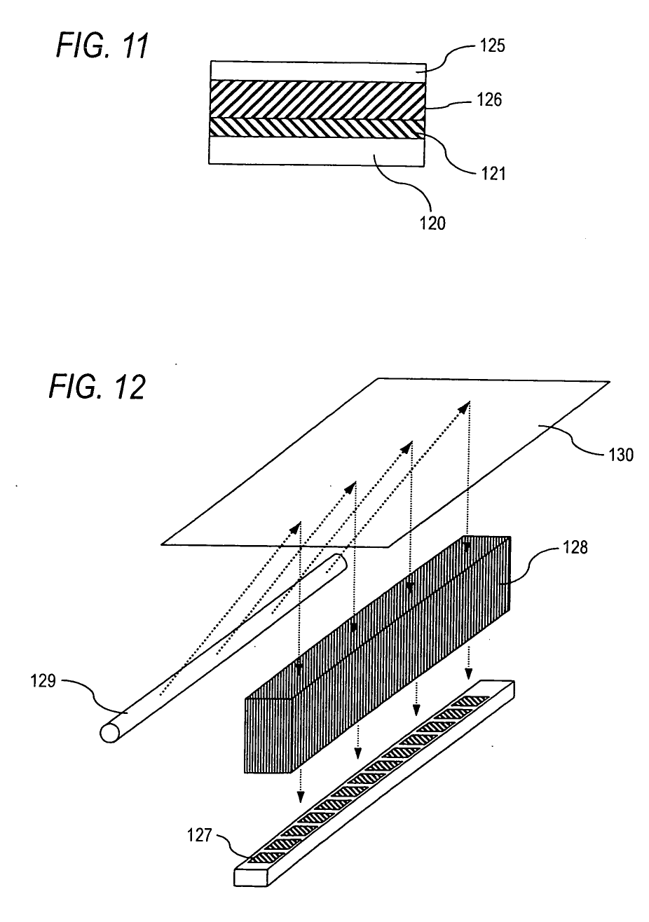

After the substrate provided with the carbon layer was taken out of the sputtering apparatus, a chlorobenzene solution containing a 1:4 weight ratio mixture of poly(2-methoxy-5-(2′-ethylhexyloxy)-1,4-phenylenevinylene) (MEH-PPV), which has the molecular structure as shown in FIG. 8 and functions as an electron donating organic material, and [5,6]-phenyl C61 butylic acid methyl ester ([5,6]-PCBM) was spin-coated on the top of the substrate. And, a photoelectric conversion region with about 100 nm thickness was formed by subjecting the coated substrate to heat treatment in a clean oven kept at 100° C. for 30 min.

Meanwhile, [5,6]-PCBM, one of modified fullerene compounds, not only readily dissolves in chlorobenzene as the solvent, thus being able to form a homogeneous photoelectric conversion region, but also has an extremely high electron acceptability. Thus, it can efficiently exchange photo-carriers between MEH-PPV as an electron donating material, achieving an excellent photoelectric conversion efficiency.

Finally, on this photoelectric conversion region, Al was deposited in a thickness of about 100 nm to give a negative electrode 12 in a resistive heating-type vapor deposition apparatus the pressure of which had been reduced to 0.27 mPa (=2×10⁻⁶ Torr) or less. In this way, an organic photodiode was fabricated.

Next, another organic photodiode for comparison was fabricated. The basic structure is the same as the above-described one using the carbon layer, but in this comparative element PEDOT:PSS, which is usually used as a buffer layer, was used instead of the carbon layer. An aqueous solution of PEDOT:PSS was placed dropwise through a 0.45 μm pore size filter on the ITO substrate that had been completed up to patterning in the aforementioned manner and uniformly spread by spin-coating. By heating the coated product in a clean oven kept at 200° C. for 10 min, a buffer layer with 60 nm thickness was formed. On this layer, a photoelectric conversion region and a negative electrode were formed with the aforementioned materials and procedures to give an organic photodiode for comparison.

Then, the current-voltage characteristics of these two types of organic photodiode were evaluated. FIG. 9 shows the results of measuring the current value flowing through each organic photodiode by applying potential between the two electrodes of the organic photodiode under the two conditions of 50 lux white light irradiation and of total darkness under light-shielding.

As shown in the drawing, the element having the inserted PEDOT buffer layer exhibits a small difference between the photo- and dark currents, because of a large dark current under reverse bias application. But in the element having the inserted carbon layer in accordance with the invention, the dark current could be markedly suppressed. Accordingly, the S/N ratio represented by the difference between the photo- and dark currents could also be remarkably improved. Namely, when a reverse bias of 1 volt was applied, the S/N ratio of 2 dB for the PEDOT-inserted element was improved to 61 dB by virtue of inserting the carbon layer. In this way, by inserting a carbon layer into an organic photodiode, it has been confirmed that the dark current under reverse bias application can be markedly reduced and that the carbon layer has a large effect on the improvement of S/N ratio.

Since the organic photodiode of the invention can be used as a stable capacitance with a low dark current under reverse bias application, and has a high S/N ratio, it is possible to apply the photodiode to image sensors operated in charge accumulation mode.

According to third aspect of the invention, an organic diode comprises at least a pair of electrodes, and a hetero-junction layer provided between the electrodes containing at least an electron donating material and at least an electron accepting material mixed together, and a carbon layer arranged between the hetero junction layer and at least one of the pair of electrodes. By introducing the carbon layer, the dark current of a bulk hetero-junction type diode in which a p-type material and an n-type material are mixed together can exhibit high rectification performance. By way of precaution, the term “mixing” here indicates mixing in a liquid or solid state, and includes the state of a film obtained by spin-coating the resultant mixture.

Further, at least a part of the electron donating material and the electron accepting material consists of a polymer material. Thus, not only film formation is possible by spin coating or inkjet process with use of the materials dissolved in a variety of solvents, but also an organic diode excelling in thermal stability can be provided.

Further, the electron donating material and the electron accepting material entirely consist of polymer materials. Thus, not only film formation is possible by spin coating or inkjet process with use of the materials dissolved in a variety of solvents, but also an organic diode excelling in thermal stability can be provided.

Further, at least a part of the electron donating material and electron accepting material contains at least one compound selected from the group consisting of modified or unmodified fullerene compounds and carbon nano-tube compounds. An organic diode with high performance and high reliability can be provided due to the excellent carrier transport capability as well as thermal stability.

Further, the hetero-junction layer is shielded from the light impinging from the outside of the element. When light is irradiated on an ordinary pn junction, the photo-carrier generated by the photoelectric effect of the junction is taken out to the outside of the diode, thus disturbing the current-voltage characteristics. This phenomenon is serious when the diode is used at a place where light is incident or in the vicinity of a light-emitting unit. However, since the hetero-junction layer in the organic diode of the invention is light-shielded, it is possible to provide a stable diode free of malfunctions due to external disturbing light.

Further, the hetero-junction layer has a function of converting light into electricity. Thus, it is possible to provide a photodiode applicable to high S/N ratio photo-sensors and the like.

Further, the carbon layer arranged in the aforementioned organic diode has a thickness of from 5 nm to 100 nm, preferably from 10 nm to 50 nm. As a result of the concentrated study carried out on the effect of the thickness of the carbon layer inserted in the organic diode, the present inventors found that a layer thickness of 5 nm or more is effective for the reduction of the dark current. But, though the effect of dark current suppression improves with the increase of the carbon layer thickness, an excessively large carbon layer thickness results in the absorption of incident light, thus adversely affecting the use efficiency of light. Therefore, a thickness not exceeding 100 nm is preferred. More preferably, by making the carbon layer thickness from 10 nm to 50 nm, an organic diode can be provided with which a high rectification ratio is consistently achieved.

Further, the carbon layer s formed by sputtering. The mixture layer for the BH-type organic diode can be produced by spin coating, dip coating or inkjet process whereby what is important is the flatness of the underlying plane. Since the flatness of the underlying plane has a strong influence on the quality of the resulting coated layer particularly in spin coating, it is very important how to prepare a highly flat and smooth underlying plane. From such viewpoint, the carbon layer is preferably formed by sputtering since this method exhibits desirable step coverage nature.

In the following, the organic diode of the invention is described in detail.

The substrate used for the organic diode of the invention is not specifically limited so long as it is provided with mechanical and thermal strength, exemplified by glass, various polymer materials including poly(ethylene terephthalate), polycarbonate, poly(methyl methacrylate), polyether sulfone, poly(vinyl fluoride), polypropylene, polyethylene, polyacrylate, an amorphous polyolefin, and a fluorine-containing resin, and metals including Al, Au, Cr, Cu, In, Mg, Ni, Si and Ti, Mg alloys such as Mg—Ag alloy and Mg—In alloy, Al alloys such as Al—Li alloy, Al—Sr alloy and Al—Ba alloy. Further, it is effective to use a flexible substrate obtained by fabricating these materials in the form of film or a composite substrate obtained by laminating two or more of substrate materials. Moreover, the substrate is not specifically restricted with respect to its electric conductivity though preferred to be insulating; within the range of not impeding the function of the organic diode or depending on use application, the substrate may have electro-conductivity.

As the positive and negative electrodes of the organic diode, a metal oxide such as ITO, ATO (Sb-doped SnO₂) and AZO (Al-doped ZnO), a metal such as Al, Au, Cr, Cu, In, Mg, Ni, Si and Ti, magnesium alloys exemplified by Mg—Ag alloy and Mg—In alloy, and aluminum alloys exemplified by Al—Li alloy, Al—Sr alloy and Al—Ba alloy can be adopted. Moreover, by arranging an auxiliary electrode in combination, comparatively highly resistant coating-type ITO, a variety of electro-conductive polymer compounds such as PEDOT, PPV and polyfluorene can also be used.

As the electron donating organic material, polymers of phenylenevinylene, fluorene, carbazole, indole, pyrene, pyrrole, picoline, thiophene, acetylene and diacetylene, and the derivatives thereof can be used. Moreover, the material is not restricted to polymers, but porphyrin compounds such as, for example, porphine, copper tetraphenylporphine, phthalocyanine, copper phthalocyanine, and titanium phthalocyanine oxide; aromatic tertiary amines such as 1,1-bis[4-(di-p-tolylamino)phenyl]cyclohexane, 4,4′,4″-trimethyltriphenylamine, N,N,N′,N′-tetraquis(p-tolyl)-p-phenylenediamine, 1-(N,N-di-p-tolylamino)naphthalene, 4,4′-bis(dimethylamino)-2-2′-dimethyltriphenylmethane, N,N,N′,N′-tetraphenyl-4,4′-diaminobiphenyl, N,N′-diphenyl-N,N′-di-m-tolyl-4,4′-diaminobiphenyl, and N-phenylcarbzole; stilbene compounds such as 4-di-p-tolylaminostilbene, and 4-(di-p-tolylamino)-4′-[4-(di-p-tolylamino)styryl]stilbene; triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, silazane derivatives, polysilane-based aniline copolymers, oligomers, styrylamine compounds, aromatic dimethylidyne-based compounds, and poly(3-methylthiophene) can also be used.

As the electron accepting material, in addition to low molecular weight and high polymer materials similar to the aforementioned electron donating materials, fullerene compounds represented by C60 and C70, carbon nano-tubes and their derivatives, oxadiazole derivatives such as 1,3-bis(4-tert-butylphenyl-1,3,4-oxadiazolyl)phenylene (OXD-7), anthraquinodimethane derivatives, and diphenylquinone derivatives can be used.

In addition, for the improvement of short-circuit current, the technique of introducing a metal oxide, metal fluoride or metal nitride between the organic layer and the negative electrode can preferably be adopted.

The composition and configuration of the carbon layer can be appropriately chosen. Although any type of carbon including amorphous carbon (α-C) represented by diamond-like carbon or graphite carbon may be used, those having a high specific resistance are preferably used for the purpose of the invention, i.e., the reduction of the dark current in the BH element, and amorphous carbon is particularly preferably used. Moreover, the composition of the carbon layer need not be composed of carbon alone, but carbon compounds such as carbon nitride can also be used without any trouble.

As the method of forming the aforementioned carbon layer, any one can be used so long as the method can provide a stable layer, including CVD method and sputtering. But, from the viewpoint of manufacturing cost reduction, layer formation by sputtering with use of a carbon target is preferred. The carbon target to be used, which is not specifically limited, includes isotropic graphite, anisotropic graphite and glassy carbon, among which highly purified isotropic graphite is suited. The specific resistance of the carbon layer can be arbitrarily changed depending on the type and mixing ratio of the gas for sputtering or by heat treatment after layer formation.

As the method of manufacturing the organic diode by using the above-enumerated materials, any of various vacuum processes such as vacuum vapor deposition and sputtering and wet processes such as spin coating and dipping process may be adopted whereby the one suited for the material and configuration to be used is selected at will. But, in consideration of the low cost characterizing the organic diode, a wet process, which does not require any large-scale manufacturing apparatus, is desirably adopted for the formation of the organic layers.

In the following, the best modes for carrying out the invention are described.

An organic diode in one embodiment for practicing the invention is described.

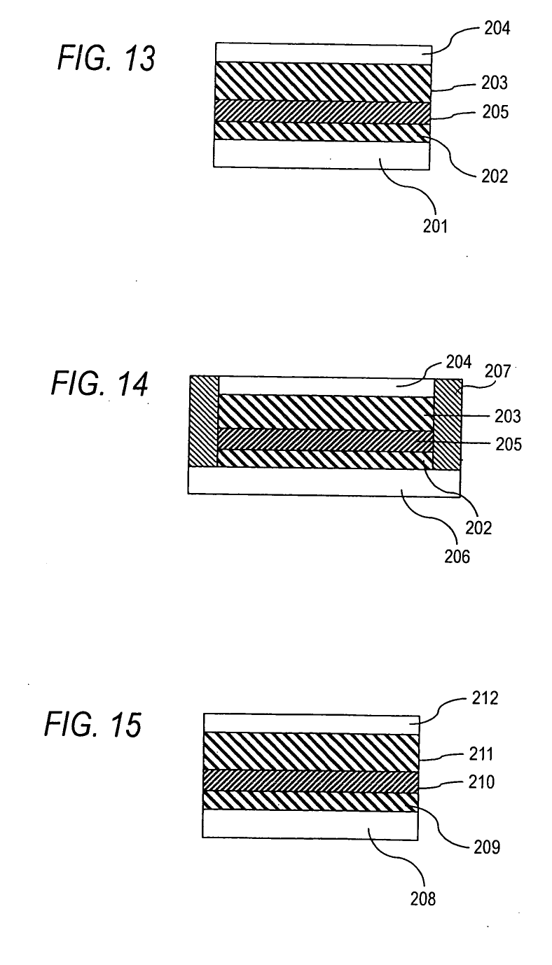

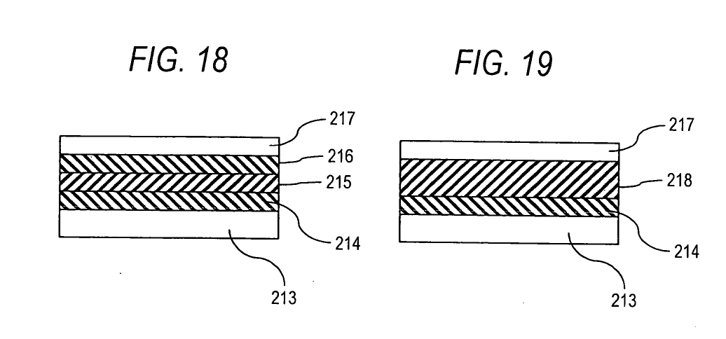

The configuration of the organic diode in the present embodiment is shown in FIG. 13. The basic configuration of element is the same as that of the conventional one as shown in FIG. 18, and a positive electrode 202, a mixture layer 203 and a negative electrode 204 are formed on a substrate 201. The point in which the organic diode of the invention is different from the conventional one is that a carbon layer 205 is inserted between the mixture layer and an electrode. In the present embodiment, the configuration is described in which the carbon layer is inserted between the positive electrode and the mixture layer. But, the inserted position of the carbon layer is not limited to the above one, but, for example, the carbon layer may be inserted between the mixture layer and the negative electrode, or, when a buffer layer such as one comprising PEDOT:PSS (a mixture of polythiophene and polystyrenesulfonic acid) is used, between the buffer layer and an electrode, or between the buffer layer and the mixture layer without any trouble.

In the BH-type organic diode, the pn junction spreads throughout the entire organic layer, whereby no definite hetero-junction is formed as in the case of an inorganic diode. Therefore, the rectifying property of the diode is determined by the work function of each electrode, the carrier transport capability as well as the carrier blocking capability of the buffer layer. The polymer material called PEDOT:PSS has been used mainly as a buffer layer for a positive electrode because of its advantages of simple film formation, sparing solubility in various organic solvents enabling the ready formation of an organic thin film thereon. However, the carrier blocking capability of this material was not so high, and thus generation of a dark current when a reverse bias is applied could not be suppressed.

But, according to the configuration of the invention wherein a carbon layer is arranged between an electrode and the hetero-junction layer, not only remarkable suppression of carrier injection into the photoelectric region from the electrode under a reverse bias application is achieved, but also marked dark current reduction is possible since the mixture layer is formed on a smooth carbon layer whereby the occurrence of physical defects such as pin holes is prevented. As the carbon layer has a resistance, the decrease of current in normal direction also inevitably occurs. But, due to a larger decrease of the dark current under reverse bias application, a higher rectification ratio results.

Next, the mixture layer comprising an organic p-type semiconductor material and an organic n-type semiconductor material is explained. As stated previously, the invention uses the mixture of an organic p-type semiconductor material and an organic n-type semiconductor material for the pn junction portion. This fact is very important for achieving a low manufacturing cost as a significant feature of the organic diode. The mixture layer may be formed, for example, even by a dry process wherein the organic materials are simultaneously vapor deposited. But, to achieve cost reduction, adoption of a wet process such as spin coating, inkjet process and spray coating is preferred since they do not require any large-scale apparatus. Therefore, the organic diode of the invention uses a polymer material as at least a part of the constituent elements of the mixture layer. Since the use of a polymer material makes the viscosity control of the solution easy, the regulation of the thickness after film formation can be carried out in a simple manner, leading to an inexpensive manufacture of an organic diode exhibiting consistent performance. As the material to be mixed with such a polymer material, the various polymer materials and low molecular weight materials enumerated above can be appropriately used depending on use applications. For example, by formulating the mixture layer entirely only with polymer materials, formation of the film via a wet process such as spin coating can be conducted, imparting excellent thermal stability simultaneously.

Moreover, by forming the mixture layer with an electron donating polymer material together with a fullerene compound or a carbon nano-tube compound, an organic diode with a high rectification ratio can be attained. Fullerenes and carbon nano-tube compounds, which have very high electron accepting capability, are characterized by a very high rectification ratio even for a BH-type organic diode due to the capability of forming a very good pn junction with an electron donating material. To uniformly solve a fullerene compound with a polymer material together, modification of the fullerene is effective to enhance the solubility in solvents. For example, [6,6]-PCBM ([6,6]-phenyl C61-butylic acid methyl ester) is preferably adopted.

The carbon layer used in the invention can be formed by sputtering in an atmosphere comprising Ar gas, N₂ gas or mixtures of these. As the carbon, any type may be adopted so long as the specific resistance is sufficiently high, and amorphous carbon (α-C) or amorphous carbon nitride (α-CN) is preferably applied.

An organic diode in another embodiment practicing the invention is described. The basic configuration of the organic diode in the present embodiment is shown in FIG. 14. The basic configuration of the organic diode is the same as the above-described embodiment. The point that the organic diode in the present embodiment is different from that in Best Mode 1 is that the hetero-junction layer comprising a mixture layer is light-shielded, and that a light-shielding substrate 6 and a light-shielding member 207 are provided for that purpose. When light is irradiated onto the pn junction, photo-current generates due to the photoelectric effect thereof. And the current affects the rectification property of the diode. Thus, in the invention, to avert this trouble, a configuration is adopted with which light does not impinge on the hetero-junction portion. As the light-shielding substrate, in addition to silicon wafer and various metals, glass or polymer materials combined with a metal film are appropriately used. And, in some cases, it is possible to shield light from the substrate side by providing a light-shielding positive electrode comprising a metal. By light-shielding the entire hetero-junction layer in such a manner with use of a light-shielding material, an organic diode having a rectification property stabilized for light irradiation can be provided. Meanwhile, the organic diode of the invention, which uses organic semiconductor materials as the constituent materials thereof, has another feature of an extremely high thermal stability due to a small number of carriers compared with that of inorganic semiconductor materials.

An organic diode in one embodiment practicing the invention is described.

The configuration of the organic diode in the present embodiment is the same as in FIG. 13. The point that the organic diode in the present embodiment is different from conventional ones lies in that the hetero-junction layer acts as a photodiode, having a photoelectric conversion function with which light is converted to electricity. Even so far, the BH-type organic diode has been developed for solar cell application, and, as a matter of course, has photoelectric conversion capability. However, the use application of the diode of the conventional type has been restricted due to the difficulty of charge accumulation in the element because of the large dark current under reverse bias application. In contrast, since the organic diode of the invention has markedly reduced the dark current by inserting a carbon layer, the diode can be used in various applications as a photodiode.

An organic diode in another embodiment practicing the invention is described. The configuration of the element is the same as the one shown in FIG. 13. In the organic diode of the invention, the thickness of the carbon layer is 5 nm to 100 nm, and preferably 10 nm to 50 nm. As described previously, the carbon layer is preferably formed by sputtering with use of a carbon target. In the formation of the carbon layer by sputtering, reactive sputtering is carried out in an atmosphere of a mixed gas consisting of nitrogen or hydrogen with argon in order to control the electric resistance of the carbon layer. In such a case, when the layer thickness does not exceed 5 nm, the layer assumes an island-like structure, failing in forming a stable organic photodiode since the layer is not homogeneous. In contrast, when the layer is as thick as 100 nm or more, the light amount reaching the mixture layer decreases due to the resistance of the carbon layer itself, making the normal direction current difficult to flow. Accordingly, a layer thickness between 5 nm and 100 nm is preferred, and, for the balance of the normal direction and reverse direction currents, a thickness between 10 nm and 50 nm is more preferred.

An organic diode in another embodiment practicing the invention is described. The carbon layer used in the organic diode of the invention is formed by sputtering. In the case of carbon layer formation via sputtering, the electric resistance and light transmittance of the layer can be easily controlled by changing the mixing ratio of the atmospheric gas. Thus, carbon layers having arbitrary electric as well as optical properties can be produced. In addition, when the hetero-junction portion of the organic diode is formed by a wet process such as spin coating or inkjet process, the flatness of the carbon layer that acts as the underlying plane is very important. Since the hetero-junction portion is formed in the form of an extremely thin film, defects are likely to occur if the flatness of the underlying carbon layer is poor, and there is a possibility that the rectification performance is affected by such defects. For this problem, sputtering is also effective. Since a carbon layer prepared by sputtering is very flat, no problem takes place at all when a hetero-junction portion is formed on the layer. Further, in the case where the carbon layer is formed by sputtering, the layer grows isotropically relative to the underlying plane to show high step coverage, thus exerting the effect of mitigating an electrode step difference. Thus, it is possible to suppress the shorting at the electrode end portion.

### EXAMPLE

Now, an actual manufacturing process of an organic diode and the characteristics of the resulting organic diode are described with reference to the drawings. FIG. 15 is a configurational drawing of an organic diode produced in the present example.

First of all, on a glass substrate 208, an ITO film with 150 nm thickness was formed by sputtering. On this ITO film a 5 μm thick resist film with was provided by spin-coating a resist material (OFPR-800 of Tokyo Ohka Kogyo Co., Ltd.). Then, via masking, exposure and development, the resist film was patterned.

Then, after immersed in an 18 N aqueous hydrochloric acid kept at 60° C. to etch the ITO film at the portion where no resist film is present, this glass substrate was washed with water. Finally, by removing the resist film, a positive electrode 209 consisting of the ITO film in a pre-determined pattern was obtained.

Then, this glass substrate was subjected to ultrasonic rinsing with a detergent (Semico-clean, a product of Furuuchi Chemical Corp.) for 5 min, ultrasonic rinsing with pure water for 10 min, ultrasonic rinsing for 5 min with a solution obtained by mixing 1 part (by volume) of aqueous hydrogen peroxide and 5 parts of water with 1 part of aqueous ammonia, and ultrasonic rinsing with 70° C. purified water for 5 min successively in this order. Thereafter, the water adhering the glass substrate was removed with use of a nitrogen blower, and further heating to 250° C. dried the substrate.

In succession, the glass substrate on which the positive electrode had been thus formed was placed in a sputtering apparatus. And, after the pressure of the apparatus was reduced to the degree of vacuum of 0.68 mPa (=5×10⁻⁶ Torr) or less, a carbon layer was formed. A 50 nm thick carbon layer was formed by using graphite carbon as the target and adopting the following sputtering conditions: atmospheric gas=a 50/50 mixture of argon and nitrogen, gas pressure=0.68 Pa (=5×10⁻³ Torr), power=300 W, and sputtering time=3 min.

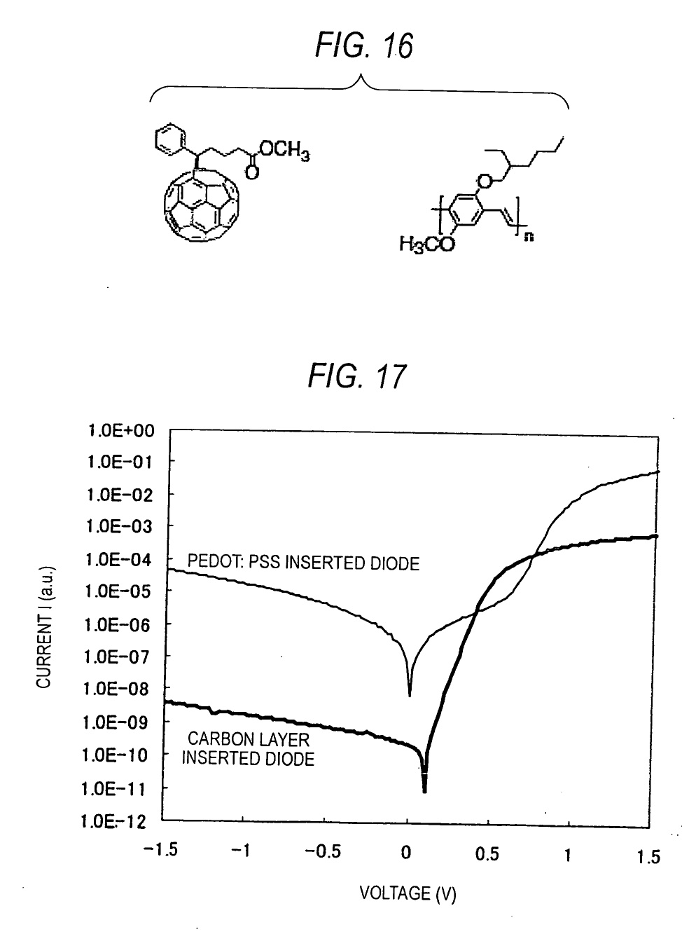

After the substrate that had been finished up to the step of carbon layer formation was taken out of the sputtering apparatus, a chlorobenzene solution containing a 1:4 weight ratio mixture of poly(2-methoxy-5-(2′-ethylhexyloxy)-1,4-phenylenevinylene) (MEH-PPV), which has the molecular structure as shown in FIG. 16 and functions as an electron donating organic material, and [5,6]-phenyl C61 butylic acid methyl ester ([5,6]-PCBM) was spin-coated on the top of the substrate. And, an organic mixture layer was formed with about 100 nm thickness by subjecting the coated substrate to heat treatment in a clean oven kept at 100° C. for 30 min.

Meanwhile, [5,6]-PCBM, one of modified fullerene compounds, has an extremely large electron mobility, and thus can form an extremely excellent hetero-junction even in the form of mixed film with MEH-PPV as an electron donating material.

Finally, on this mixture layer, Al was deposited in a thickness of about 100 nm to give a negative electrode 212 in a resistive heating-type vapor deposition apparatus the pressure of which was reduced to 0.27 mPa (=2×10⁻⁶ Torr) or less. In this way, an organic diode was fabricated.

Next, another organic diode for comparison was fabricated. The basic structure is the same as the above-described one using the carbon layer, but in this comparative element, PEDOT:PSS, which is usually used as a buffer layer, was used instead of the carbon layer. An aqueous solution of PEDOT:PSS was placed dropwise through a 0.45 μm pore size filter on the ITO substrate that had been completed up to patterning in the aforementioned manner and uniformly spread by spin-coating. By heating the coated product in a clean oven kept at 200° C. for 10 min, a buffer layer with 60 nm thickness was formed. On this layer, a hetero-junction layer and a negative electrode were formed to complete an organic diode for comparison.

The current-voltage characteristics of these two organic diodes are shown in FIG. 17. As is seen in the drawing, though the normal direction current is slightly lowered in the carbon layer-inserted organic diode, the reverse direction current shows a far larger decrease, thus resulting in a marked improvement of rectification capability. An intense effect of the carbon layer on the improvement of rectification capability has been confirmed.

### EXAMPLE

Next, the relationship between the carbon layer thickness and the rectification capability of the organic diode is described. First of all, a series of organic diodes were produced in the same manner as in above Example but by changing the carbon layer thickness. The layer thickness was changed by controlling the sputtering time so as to give organic diodes with 5, 10, 30, 50, 100 and 200 nm thick carbon layers. Further, in the present example, the organic diode in which the carbon layer was replaced by a 60 nm thick PEDOT:PSS layer was used as the comparative example. By measuring the current-voltage characteristics of each of these organic diodes under a light-shielded condition, the rectification ratio was derived. Though the diode having the 5 nm or 200 nm thick carbon layer exhibited substantially the same rectification ratio as that of the comparative example using the PEDOT:PSS layer, the remaining ones each having the 10, 30, 50 or 100 nm thick carbon layer exhibited larger rectification ratios than that of the comparative example. In particular, the element having the 30 nm thick carbon layer showed an improvement in rectification capability of more than two orders of magnitude.

Since the organic diode of the invention has a high rectification ratio, and can stably operate under an extensive range of environmental condition, it can be applied to various electric circuits represented by the driving circuit for organic electronic devices.

This application is based upon and claims the benefit of priority of Japanese Patent Application No. 2004-102861 filed on Mar. 31, 2004, No. 2005-72555 and No. 2005-72556 both filed on Mar. 15, 2005, the contents of which are incorporated herein by reference in its entirety.

1. An organic photoelectric conversion element comprising:
at least a pair of electrodes; and
a photoelectric conversion region arranged between the electrodes and containing at least an electron donating organic material and an electron accepting material,
wherein a buffer layer comprising at least one inorganic material is arranged between the photoelectric conversion region and at least one of the pair of electrodes.

2. The organic photoelectric conversion element set forth in claim 1, wherein the photoelectric conversion region contains an organic thin film.

3. The organic photoelectric conversion element set forth in claim 2, wherein the organic thin film includes a polymer film which has been formed by coating on one surface of the electrode.

4. The organic photoelectric conversion element set forth in claim 2, wherein the electron donating material includes one consisting of an electroconductive polymer material.

5. The organic photoelectric conversion element set forth in claim 1, wherein the electron accepting material contains at least one of a modified or unmodified fullerene compound and a carbon nano-tube compound.

6. The organic photoelectric conversion element set forth in claim 1, wherein the buffer layer contains an oxide.

7. The organic photoelectric conversion element set forth in claim 6, wherein the buffer layer contains a transient metal oxide.

8. The organic photoelectric conversion element set forth in claim 7, wherein the buffer layer contains the oxide of molybdenum or vanadium.

9. The organic photoelectric conversion element set forth in claim 1, wherein the buffer layer contains a nitride.

10. The organic photoelectric conversion element set forth in claim 9, wherein the buffer layer contains a transient metal nitride.

11. The organic photoelectric conversion element set forth in claim 1, wherein the buffer layer contains an oxy-nitride.

12. The organic photoelectric conversion element set forth in claim 11, wherein the buffer layer contains a transient metal oxy-nitride.

13. The organic photoelectric conversion element set forth in claim 1, wherein the buffer layer contains a complex oxide containing a transient metal.

14. The organic photoelectric conversion element set forth in claim 1, wherein the photoelectric conversion region contains an electron donating layer containing an electron donating organic material and an electron accepting layer containing an electron accepting material.

15. The organic photoelectric conversion element set forth in claim 1, wherein the buffer layer is arranged between the electron donating layer and the electrode.

16. The organic photoelectric conversion element set forth in claim 1, wherein the buffer layer is arranged between the electron accepting layer and the electrode.

17. The organic photoelectric conversion element set forth in claim 1, wherein the photoelectric conversion region contains an organic semiconductor layer in which an electron donating organic material and an electron accepting material are dispersed.

18. A method of producing an organic photoelectric conversion element, comprising:
a step of forming an electrode;
a step of forming a buffer region containing an inorganic matter;
a step of forming an organic photoelectric conversion region; and
a step of forming an electrode on the organic photoelectric conversion region.

19. The method of producing an organic photoelectric conversion element set forth in claim 18, wherein the step of forming a buffer region includes a step of forming the buffer layer by a wet process.

20. An organic photodiode comprising:
at least a pair of electrodes; and
a photoelectric conversion region provided between the electrodes and containing at least an electron donating material and at least an electron accepting material; and
a carbon layer arranged between the photoelectric conversion region and at least one of the pair of electrodes, which accumulate electric charge.

21. The organic photodiode set forth in claim 20, wherein said photoelectric conversion region containing at least an electron donating material and at least an electron accepting material mixed together.

22. The organic photodiode set forth in claim 20, wherein at least a part of the electron donating material and the electron accepting material in said photoelectric conversion region consists of a polymer material.

23. The organic photodiode set forth in claim 20, wherein the electron donating material and the electron accepting material in said photoelectric conversion region entirely consist of polymer materials.

24. The organic photodiode set forth in claim 20, wherein at least a part of the electron donating material and the electron accepting material in said photoelectric conversion region contains at least one compound selected from the group consisting of modified or unmodified fullerene compounds and carbon nano-tube compounds.

25. An organic photodiode set forth in claim 20, wherein the carbon layer arranged therein has a thickness of from 5 nm to 100 nm.

26. An organic photodiode set forth in claim 20, wherein the carbon layer arranged therein has a thickness of from 10 nm to 50 nm.

27. An image sensor comprises a organic photodiode as the photo-receptive part, the organic photodiode comprising:
at least a pair of electrodes; and
a photoelectric conversion region provided between the electrodes and containing at least an electron donating material and at least an electron accepting material mixed together; and
a carbon layer arranged between the photoelectric conversion region and at least one of the pair of electrodes, which accumulate electric charge.

28. An image sensor set forth in claim 27 wherein the photo-receptive part thereof is linearly arranged and constitutes a line sensor.

29. An image sensor set forth in claim 27 wherein the photo-receptive part thereof is arranged in a two-dimensional planar area form and constitutes an area sensor.

30. The image sensor set forth in claim 27, wherein the degree of light quantity is judged by reducing the accumulated charge with the charge generated in the organic photodiode after charge accumulation by the application of an external bias potential to the organic photodiode in advance.

31. An organic diode comprising:
at least a pair of electrodes; and
a hetero-junction layer provided between the electrodes and containing at least an electron donating material and at least an electron accepting material mixed together; and
a carbon layer arranged between the hetero-junction layer and at least one of the pair of electrodes.

32. The organic diode set forth in claim 31, wherein at least a part of the electron donating material and the electron accepting material consists of a polymer material.

33. The organic diode set forth in claim 31, wherein the electron donating material and the electron accepting material entirely consist of polymer materials.

34. The organic diode set forth in claim 31, wherein at least a part of the electron donating material and electron accepting material contains at least one compound selected from the group consisting of modified or unmodified fullerene compounds and carbon nano-tube compounds.

35. The organic diode set forth in claim 31, wherein the hetero-junction layer is shielded from the light from the outside of the element.

36. The organic diode set forth in claim 31, wherein the hetero-junction layer has a function of converting light into electricity.

37. The organic diode set forth in claim 31, wherein the thickness of the carbon layer arranged in the organic diode is from 5 nm to 100 nm.

38. The organic diode set forth in claim 31, wherein the thickness of the carbon layer arranged in the organic diode is from 10 nm to 50 nm.

39. The organic diode set forth in claim 31, wherein the carbon layer is formed by sputtering.
